(19) United States
(12) Patent Application Publication
(10) Pub. No.: US 2026/0282350 A1
(43) Pub. Date: Sep. 17, 2026

(54) MEMORY DEVICE

(71) Applicant: Kioxia Corporation, Tokyo (JP)

(72) Inventors: Ryo FUKUOKA, Yokkaichi Mie (JP); Fumitaka ARAI, Yokkaichi Mie (JP)

(73) Assignee: Kioxia Corporation, Tokyo (JP)

(21) Appl. No.: 19/323,833

(22) Filed: Sep. 9, 2025

(30) Foreign Application Priority Data
Mar. 17, 2025 (JP) 2025-042801

(51) Int. Cl. H10B 41/35; H10B 41/10; H10B 41/27

(52) U.S. Cl. CPC H10B 41/35; H10B 41/10; H10B 41/27

(57) ABSTRACT

According to one embodiment, a memory device includes: first and second conductive pillars each extending a first direction and arranged in a second direction; third and fourth conductive pillars each extending the first direction at a position shifted from the first and second conductive pillars in a third direction and arranged in the second direction; a first semiconductor film between the first and third conductive pillar; a second semiconductor film between the second and fourth conductive pillars; a first insulator film between the second and third conductive pillars; first and third charge storage films between the respective first and third conductive pillars and the first semiconductor film; second and fourth charge storage films between the respective second and fourth conductive pillars and the second semiconductor film. The third conductive pillar is between the first and second conductive pillars. The second conductive pillar is between the third and fourth conductive pillars.

### CROSS-REFERENCE TO RELATED APPLICATIONS

This application is based upon and claims the benefit of priority from Japanese Patent Application No. 2025-042801, filed Mar. 17, 2025, the entire contents of which are incorporated herein by reference.

### FIELD

Embodiments described herein relate generally to a memory device.

### BACKGROUND

As a memory device that can store data in a nonvolatile manner, a NAND flash memory is known. A memory device like a NAND flash memory uses a three-dimensional memory structure for high integration and large capacity.

### BRIEF DESCRIPTION OF THE DRAWINGS

FIG. 1 is a block diagram showing an example of a configuration of a memory system including a memory device according to a first embodiment.

FIG. 2 is a circuit diagram showing an example of a circuit configuration of a memory cell array of the memory device according to the first embodiment.

FIG. 3 is a plan view showing an example of a planar layout of the memory device according to the first embodiment.

FIG. 4 is a sectional view taken along line IV-IV of FIG. 3, showing an example of a sectional structure of the memory cell array according to the first embodiment.

FIG. 5 is a sectional view taken along line V-V of FIG. 4, showing a first example of a sectional structure of a memory cell transistor of the memory cell array according to the first embodiment.

FIG. 6 is a sectional view taken along line VI-VI of FIG. 4, showing a second example of a sectional structure of a memory cell transistor of the memory cell array according to the first embodiment.

FIG. 7 is a plan view showing an example of a planar layout of a memory device in progress according to the first embodiment.

FIG. 8 is a sectional view showing an example of a sectional structure of the memory device in progress according to the first embodiment.

FIG. 9 is a plan view showing an example of a planar layout of the memory device in progress according to the first embodiment.

FIG. 10 is a sectional view showing an example of a sectional structure of the memory device in progress according to the first embodiment.

FIG. 11 is a plan view showing an example of a planar layout of the memory device in progress according to the first embodiment.

FIG. 12 is a sectional view showing an example of a sectional structure of the memory device in progress according to the first embodiment.

FIG. 13 is a plan view showing an example of a planar layout of the memory device in progress according to the first embodiment.

FIG. 14 is a sectional view showing an example of a sectional structure of the memory device in progress according to the first embodiment.

FIG. 15 is a plan view showing an example of a planar layout of the memory device in progress according to the first embodiment.

FIG. 16 is a sectional view showing an example of a sectional structure of the memory device in progress according to the first embodiment.

FIG. 17 is a plan view showing an example of a planar layout of the memory device in progress according to the first embodiment.

FIG. 18 is a sectional view showing an example of a sectional structure of the memory device in progress according to the first embodiment.

FIG. 19 is a plan view showing an example of a planar layout of the memory device in progress according to the first embodiment.

FIG. 20 is a sectional view showing an example of a sectional structure of the memory device in progress according to the first embodiment.

FIG. 21 is a plan view showing an example of a planar layout of the memory device in progress according to the first embodiment.

FIG. 22 is a sectional view showing an example of a sectional structure of the memory device in progress according to the first embodiment.

FIG. 23 is a plan view showing an example of a planar layout of the memory device in progress according to the first embodiment.

FIG. 24 is a sectional view showing an example of a sectional structure of the memory device in progress according to the first embodiment.

FIG. 25 is a plan view showing an example of a planar layout of the memory device in progress according to the first embodiment.

FIG. 26 is a sectional view showing an example of a sectional structure of the memory device in progress according to the first embodiment.

FIG. 27 is a plan view showing an example of a planar layout of the memory device in progress according to the first embodiment.

FIG. 28 is a sectional view showing an example of a sectional structure of the memory device in progress according to the first embodiment.

FIG. 29 is a plan view showing an example of a planar layout of the memory device in progress according to the first embodiment.

FIG. 30 is a sectional view showing an example of a sectional structure of the memory device in progress according to the first embodiment.

FIG. 31 is a sectional view showing an example of a sectional structure of a memory cell array according to a second embodiment.

FIG. 32 is a sectional view taken along line XXXII XXXII of FIG. 31, showing a first example of a sectional structure of a memory cell transistor of the memory cell array according to the second embodiment.

FIG. 33 is a sectional view taken along line XXXIII XXXIII of FIG. 31, showing a second example of a sectional structure of the memory cell transistor of the memory cell array according to the second embodiment.

FIG. 34 is a plan view showing an example of a planar layout of a memory device in progress according to the second embodiment.

FIG. 35 is a sectional view showing an example of a sectional structure of the memory device in progress according to the second embodiment.

FIG. 36 is a plan view showing an example of a planar layout of the memory device in progress according to the second embodiment.

FIG. 37 is a sectional view showing an example of a sectional structure of the memory device in progress according to the second embodiment.

FIG. 38 is a plan view showing an example of a planar layout of the memory device in progress according to the second embodiment.

FIG. 39 is a sectional view showing an example of a sectional structure of the memory device in progress according to the second embodiment.

FIG. 40 is a plan view showing an example of a planar layout of the memory device in progress according to the second embodiment.

FIG. 41 is a sectional view showing an example of a sectional structure of the memory device in progress according to the second embodiment.

FIG. 42 is a plan view showing an example of a planar layout of the memory device in progress according to the second embodiment.

FIG. 43 is a sectional view showing an example of a sectional structure of the memory device in progress according to the second embodiment.

FIG. 44 is a plan view showing an example of a planar layout of the memory device in progress according to the second embodiment.

FIG. 45 is a sectional view showing an example of a sectional structure of the memory device in progress according to the second embodiment.

FIG. 46 is a plan view showing an example of a planar layout of the memory device in progress according to the second embodiment.

FIG. 47 is a sectional view showing an example of a sectional structure of the memory device in progress according to the second embodiment.

FIG. 48 is a plan view showing an example of a planar layout of the memory device in progress according to the second embodiment.

FIG. 49 is a sectional view showing an example of a sectional structure of the memory device in progress according to the second embodiment.

FIG. 50 is a plan view showing an example of a planar layout of the memory device in progress according to the second embodiment.

FIG. 51 is a sectional view showing an example of a sectional structure of the memory device in progress according to the second embodiment.

FIG. 52 is a plan view showing an example of a planar layout of the memory device in progress according to the second embodiment.

FIG. 53 is a sectional view showing an example of a sectional structure of the memory device in progress according to the second embodiment.

FIG. 54 is a plan view showing an example of a planar layout of the memory device in progress according to the second embodiment.

FIG. 55 is a sectional view showing an example of a sectional structure of the memory device in progress according to the second embodiment.

FIG. 56 is a plan view showing an example of a planar layout of the memory device in progress according to the second embodiment.

FIG. 57 is a sectional view showing an example of a sectional structure of the memory device in progress according to the second embodiment.

FIG. 58 is a plan view showing an example of a planar layout of the memory device in progress according to the second embodiment.

FIG. 59 is a sectional view showing an example of a sectional structure of the memory device in progress according to the second embodiment.

FIG. 60 is a plan view showing an example of a planar layout of the memory device in progress according to the second embodiment.

FIG. 61 is a sectional view showing an example of a sectional structure of the memory device in progress according to the second embodiment.

FIG. 62 is a plan view showing an example of a planar layout of the memory device in progress according to the second embodiment.

FIG. 63 is a sectional view showing an example of a sectional structure of the memory device in progress according to the second embodiment.

### DETAILED DESCRIPTION

In general, according to one embodiment, a memory device includes a first conductive pillar and a second conductive pillar each extending in a first direction, and arranged in a second direction intersecting the first direction; a third conductive pillar and a fourth conductive pillar each extending in the first direction at a position shifted from the first conductive pillar and the second conductive pillar in a third direction intersecting the first direction and the second direction, and arranged in the second direction; a first semiconductor film provided between the first conductive pillar and the third conductive pillar at a first position in the first direction; a second semiconductor film provided between the second conductive pillar and the fourth conductive pillar at the first position; a first insulator film provided between the second conductive pillar and the third conductive pillar at the first position; a first charge storage film provided between the first conductive pillar and the first semiconductor film; a second charge storage film provided between the second conductive pillar and the second semiconductor film; a third charge storage film provided between the third conductive pillar and the first semiconductor film; and a fourth charge storage film provided between the fourth conductive pillar and the second semiconductor film. The third conductive pillar is located between the first conductive pillar and the second conductive pillar in the second direction. The second conductive pillar is located between the third conductive pillar and the fourth conductive pillar in the second direction.

Embodiments will be described below with reference to the accompanying drawings. The dimensions and ratios of each drawing are not always the same as the actual ones.

In the following description, the same reference numerals are assigned to components having almost the same functions and configurations. If it is necessary to discriminate between elements having similar configurations in particular, different letters or numbers are sometimes added to the ends of the same reference numerals.

### 1 First Embodiment

### 1.1 Configuration

### 1.1.1 Memory System

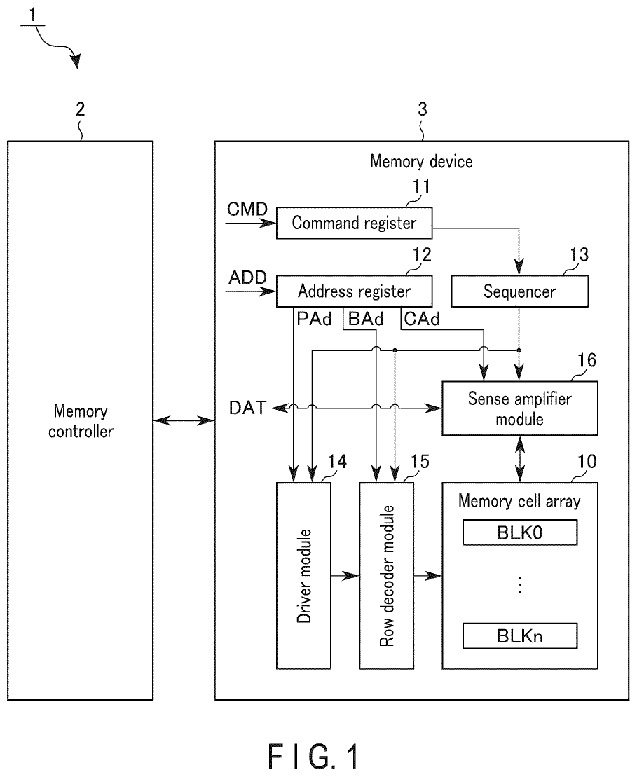

FIG. 1 is a block diagram showing an example of a configuration of a memory system including a memory device according to a first embodiment. A memory system 1 is a memory device configured to be connected to an external host (not shown). The memory system 1 is, for example, a memory card like an SD™ card, UFS (universal flash storage), or SSD (solid state drive). The memory system 1 includes a memory controller 2 and a memory device 3.

The memory controller 2 is, for example, an integrated circuit like an SoC (system-on-a-chip). The memory controller 2 controls the memory device 3 based on a request from the host. More specifically, for example, the memory controller 2 writes the data corresponding to a write request from the host to the memory device 3. In addition, the memory controller 2 reads, from the memory device 3, the data corresponding to a read request from the host and transmits the data to the host.

The memory device 3 is a nonvolatile memory. The memory device 3 is, for example, a NAND flash memory. The memory device 3 stores data in a nonvolatile manner.

The memory controller 2 and the memory device 3 communicate with each other in compliance with, for example, an SDR (single data rate) interface, toggle DDR (double data rate) interface, or ONFI (Open NAND flash interface).

### 1.1.2 Memory Device

The internal configuration of the memory device according to the first embodiment will be further described with reference to the block diagram of FIG. 1. The memory device 3 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer equal to or more than 1). The number of blocks BLK included in the memory cell array 10 may be one. The block BLK is a set of a plurality of memory cells. The block BLK is used as, for example, a unit of data erasure. The memory cell array 10 is provided with a plurality of bit lines and a plurality of word lines. Each memory cell is associated with, for example, one bit line and one word line. The detailed configuration of the memory cell array 10 will be described later.

The command register 11 stores a command CMD received by the memory device 3 from the memory controller 2. The command CMD includes, for example, instructions for making the sequencer 13 execute a read operation, a write operation, and an erase operation.

The address register 12 stores address information ADD received by the memory device 3 from the memory controller 2. The address information ADD includes, for example, a block address BAd, a page address PAd, and a column address CAd. For example, the block address BAd, the page address PAd, and the column address CAd are respectively used to select the block BLK, a word line, and a bit line.

The sequencer 13 controls the overall operation of the memory device 3. For example, the sequencer 13 executes a read operation, a write operation, and an erase operation by controlling the driver module 14, the row decoder module 15, the sense amplifier module 16, and the like based on the command CMD stored in the command register 11.

The driver module 14 generates voltages used for a read operation, a write operation, and an erase operation. The driver module 14 applies a generated voltage to a signal line corresponding to a selected word line based on, for example, the page address PAd stored in the address register 12.

Based on the block address BAd stored in the address register 12, the row decoder module 15 selects one corresponding block BLK in the memory cell array 10. The row decoder module 15 then transfers, for example, the voltage applied to a signal line corresponding to the selected word line to the word line selected in the selected block BLK.

In a write operation, the sense amplifier module 16 applies a desired voltage to each bit line in accordance with the write data DAT received from the memory controller 2. In a read operation, the sense amplifier module 16 determines data stored in the memory cell based on the voltage of a bit line, reads the determination result, and transfers the result as the read data DAT to the memory controller 2.

### 1.1.3 Memory Cell Array

### 1.1.3.1 Circuit Configuration

The circuit configuration of the memory cell array according to the first embodiment will be described next.

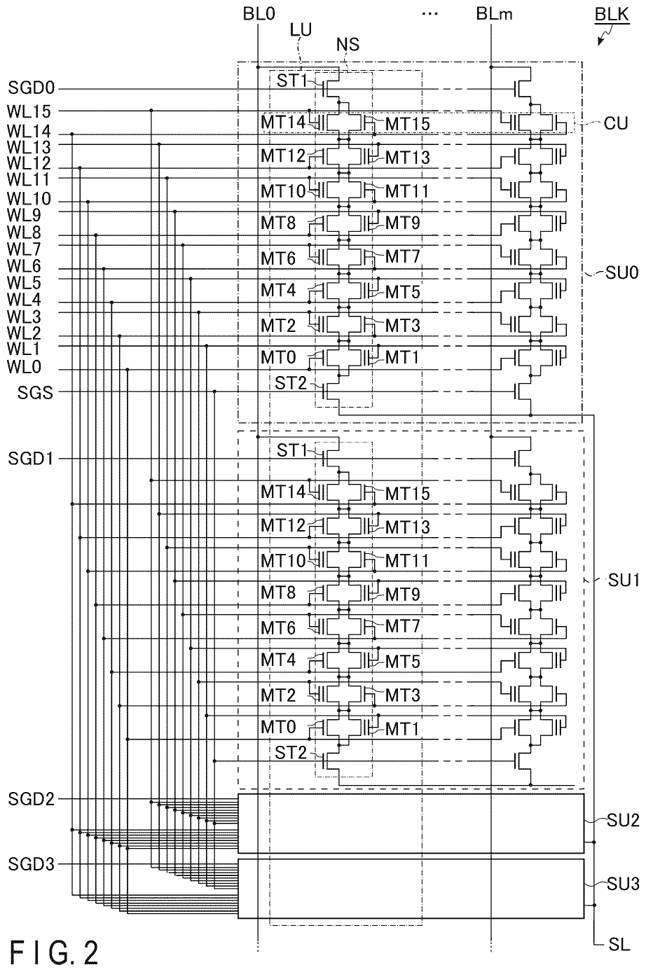

FIG. 2 is a circuit diagram showing an example of the circuit configuration of the memory cell array of the memory device according to the first embodiment. FIG. 2 shows one block BLK of the plurality of blocks BLK included in the memory cell array 10. As shown in FIG. 2, the block BLK includes, for example, four string units SU0 to SU3.

Each string unit SU includes a plurality of NAND strings NS respectively associated with bit lines BL0 to BLm (m is an integer equal to or more than 1). The number of bit lines BL may be one. Each NAND string NS includes, for example, memory cell transistors MT0 to MT15 and selection transistors ST1 and ST2. Each memory cell transistor MT includes a control gate and a charge storage film and stores data in a nonvolatile manner. The selection transistors ST1 and ST2 are used to select a string unit SU at the time of each type of operation.

In each NAND string NS, the memory cell transistors MT0 to MT15 form a current path between the selection transistor ST1 and the selection transistor ST2. More specifically, the drain of the selection transistor ST1 is connected to an associated bit line BL. The source of the selection transistor ST1 is connected to one terminal of each of the memory cell transistors MT14 and MT15. The other terminal of each of the memory cell transistors MT14 and MT15 is connected to one terminal of each of the memory cell transistors MT12 and MT13. The other terminal of each of the memory cell transistors MT12 and MT13 is connected to one terminal of each of the memory cell transistors MT10 and MT11. The other terminal of each of the memory cell transistors MT10 and MT11 is connected to one terminal of each of the memory cell transistors MT8 and MT9. The other terminal of each of the memory cell transistors MT8 and MT9 is connected to one terminal of each of the memory cell transistors MT6 and MT7. The other terminal of each of the memory cell transistors MT6 and MT7 is connected to one terminal of each of the memory cell transistors MT4 and MT5. The other terminal of each of the memory cell transistors MT4 and MT5 is connected to one terminal of each of the memory cell transistors MT2 and MT3. The other terminal of each of the memory cell transistors MT2 and MT3 is connected to one terminal of each of the memory cell transistors MT0 and MT1. The other terminal of each of the memory cell transistors MT0 and MT1 is connected to the drain of the selection transistor ST2. The source of the selection transistor ST2 is connected to a source line SL.

In the same block BLK, the control gates of the memory cell transistors MT0 to MT15 are respectively connected to the word lines WL0 to WL15. The gates of the selection transistors ST1 in the string units SU0 to SU3 are respectively connected to selection gate lines SGD0 to SGD3. The gates of the plurality of the selection transistors ST2 are connected to a selection gate line SGS.

Different column addresses are respectively assigned to the bit lines BL0 to BLm. Each bit line BL is shared by the NAND strings NS assigned with the same column address among the plurality of blocks BLK. Word lines WL0 to WL15 are provided for each block BLK. The source line SL is shared among, for example, the plurality of blocks BLK.

A set of the plurality of memory cell transistors MT connected to the common word line WL in the one string unit SU is called, for example, a cell unit. The storage capacity of a cell unit including a plurality of memory cell transistors each storing 1-bit data is defined as, for example, “1-page data”. Each cell unit can have a storage capacity of 2-page data or more in accordance with the bit count of data stored in the memory cell transistor MT.

A set of memory cell transistors MT connected to the common bit line BL in one block BLK is called, for example, a layer unit LU. The one layer unit LU includes the four NAND strings NS. The four NAND strings NS included in the one layer unit LU respectively belong to the string units SU0 to SU3.

Note that the circuit configuration of the memory cell array 10 of the memory device 3 is not limited to the configuration described above. For example, the number of string units SU included in each block BLK can be designed any number. The numbers of memory cell transistors MT and selection transistors ST1 and ST2 included in each NAND string NS can be designed any number, respectively.

### 1.1.3.2 Planar Layout

A planar layout of the memory cell array according to the first embodiment will be described next.

The memory cell array 10 is provided above a substrate. A plane parallel to the surface of the substrate will be referred to as an XY plane hereinafter. The direction in which the word line WL extends in an XY plane will be referred to as the X direction. A direction orthogonal to the X direction in an XY plane will be referred to as the Y direction. A direction extending from the substrate to the memory cell array will be referred to as the Z direction. The Z direction may be reworded as an upper direction.

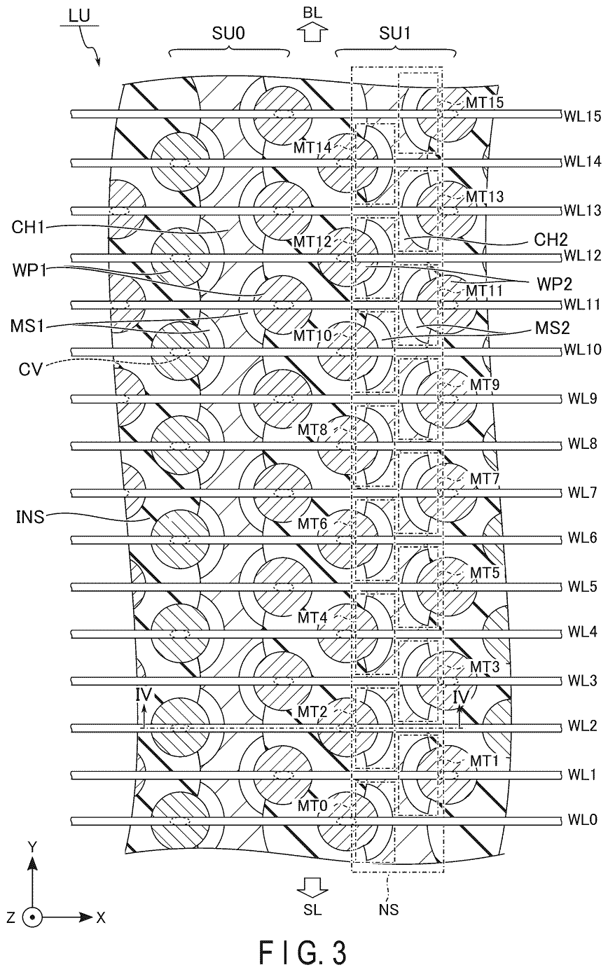

FIG. 3 is a plan view showing an example of a planar layout of the memory cell array according to the first embodiment. FIG. 3 is a plan view at a substantially equal position (in an XY plane) from the substrate in the Z direction, in the structure forming the memory cell array 10, and at a position (layer) including a structure functioning as the NAND string NS. The portion shown in FIG. 3 corresponds to the portion of the circuit diagram shown in FIG. 2 which is associated with the memory cell transistors MT of the one layer unit LU.

As shown in FIG. 3, in the same layer, the memory cell array 10 includes a plurality of conductive pillars WP1 and WP2, a plurality of channel structures CH1 and CH2, a plurality of memory structures MS1 and MS2, a plurality of insulators INS, a plurality of contacts CV, and the plurality of word lines WL.

Each of the plurality of conductive pillars WP1 and WP2 is a conductor having a columnar shape extending in the Z direction. The plurality of conductive pillars WP1 and WP2 are arranged in a 16-row staggered pattern in an XY plane. More specifically, the eight conductive pillars WP1 located on the even-numbered rows are arranged in the Y direction. The eight conductive pillars WP1 located on the odd-numbered rows are arranged in the Y direction. The eight conductive pillars WP2 located on the even-numbered rows are arranged in the Y direction. The eight conductive pillars WP2 located on the odd-numbered rows are arranged in the Y direction. The conductive pillars WP1 and the conductive pillars WP2 located on the same row are alternately arranged in the X direction.

The contact CV is provided on the upper surface of each of the conductive pillars WP1 and WP2. The plurality of contacts CV respectively provided on the plurality of conductive pillars WP1 and WP2 located on the kth row are commonly connected to the word line WLk.

The channel structure CH1 is provided between a set of the eight conductive pillars WP1 located on the even-numbered rows and a set of the eight conductive pillars WP1 located on the odd-numbered rows. The memory structure MS1 is provided between the channel structure CH1 and each of the 16 conductive pillars WP1 adjacent to the channel structure CH1.

The channel structure CH2 is provided between a set of the eight conductive pillars WP2 located on the even-numbered rows and a set of the eight conductive pillars WP2 located on the odd-numbered rows. The memory structure MS2 is provided between the channel structure CH2 and each of the 16 conductive pillars WP2 adjacent to the channel structure CH2.

Insulator INS is provided between a set of the eight conductive pillars WP1 located on the odd-numbered rows and a set of the eight conductive pillars WP2 located on the even-numbered rows. Insulator INS is provided between a set of the eight conductive pillars WP2 located on the odd-numbered rows and a set of the eight conductive pillars WP1 located on the even-numbered rows.

The one memory structure MS1, and the one conductive pillar WP1 and the one channel structure CH1 which sandwich the memory structure MS1 function as the one memory cell transistor MT. The memory cell transistor MT corresponding to the kth row conductive pillar WP1 functions as a memory cell transistor MT(k−1) (1≤k≤16). The 16 memory cell transistors MT0 to MT15 sharing the channel structure CH1 are included in the one string unit SU.

The one memory structure MS2 and the one conductive pillar WP2 and the one channel structure CH2 which sandwich the memory structure MS2 function as the one memory cell transistor MT. The memory cell transistor MT corresponding to the kth row conductive pillar WP2 functions as a memory cell transistor MT(k−1). The 16 memory cell transistors MT0 to MT15 sharing the channel structure CH2 are included in the one string unit SU.

In the example of FIG. 3, the 16 conductive pillars WP1 belong to the string unit SU0, and the 16 conductive pillars WP2 belong to the string unit SU1.

### 1.1.3.3 Sectional Structure

The sectional structure of the memory cell array according to the first embodiment will be described next.

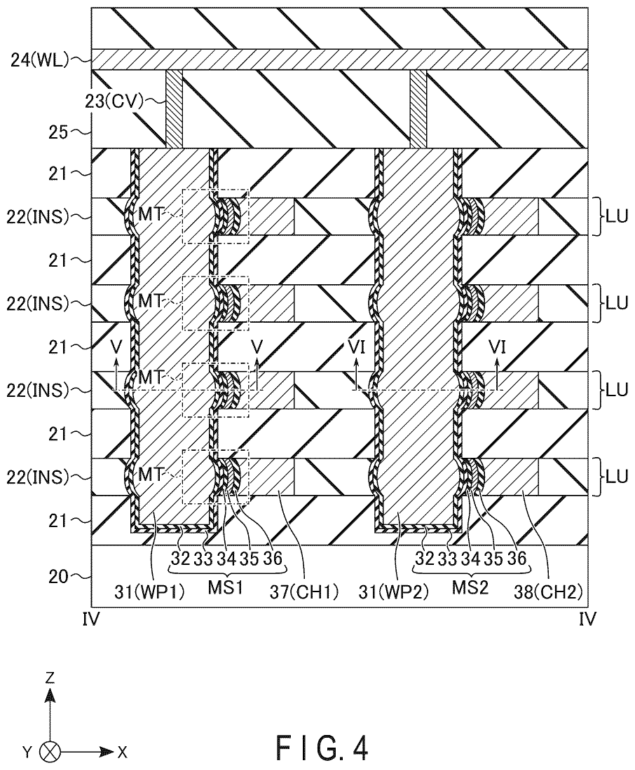

FIG. 4 is a sectional view taken along line IV-IV of FIG. 3, showing an example of the sectional structure of the memory cell array according to the first embodiment. FIG. 4 shows the sectional structure including the conductive pillar WP1 and the conductive pillar WP2 located on the same row.

As shown in FIG. 4, the memory cell array 10 includes a substrate 20, insulator layers 21, 22, and 25, conductor films 23 and 31, a conductor layer 24, insulator films 32, 33, 34, and 36, a charge storage film 35, and semiconductor films 37 and 38.

The substrate 20 is, for example, a semiconductor substrate containing silicon.

The insulator layer 21 is provided on the upper surface of the substrate 20. The insulator layer 21 contains, for example, silicon oxide (SiO₂).

The insulator layers 22 and 21 are alternately stacked on the upper surface of the insulator layer 21. The insulator layer 22 contains, for example, silicon oxide (SiO₂). The insulator layer 22 functions as the insulator INS. The layer unit LU is provided on the layer on which the insulator layer 22 is provided. In the example of FIG. 4, the four layer units LU are stacked.

The plurality of conductor films 31 are conductors extending through the insulator layers 21 and 22 in the Z direction. The lower end of each of the plurality of conductor films 31 is located below the lowermost insulator layer 22 (for example, in the lowermost insulator layer 21). The upper end of each of the plurality of conductor films 31 is located above the uppermost insulator layer 22 (for example, at the same height as the upper surface of the uppermost insulator layer 21). The conductor film 31 functions as the conductive pillar WP1 or WP2. The conductor film 31 contains, for example, titanium nitride (TiN).

The insulator film 32 is provided so as to cover the side surfaces and the lower surface of the conductor film 31. The insulator film 32 contains, for example, aluminum oxide (AlO).

The insulator film 33 is provided so as to cover the side surfaces and the lower surface of the insulator film 32. The insulator film 33 contains, for example, silicon oxide (SiO₂).

The insulator film 34 is provided on the portion of the side surface of the insulator film 33 which corresponds to the layer unit LU. The insulator films 34 corresponding to the layer units LU are spaced from each other. The insulator film 34 contains, for example, hafnium silicate (HfSiO).

The charge storage films 35 are provided on the side surfaces of the insulator films 34 corresponding to the respective layer units LU. The charge storage film 35 contains, for example, polysilicon.

The insulator films 36 are provided on the side surfaces of the charge storage films 35 corresponding to the respective layer units LU. The insulator film 36 contains, for example, silicon oxide (SiO₂).

In the above configuration, a set of the insulator films 32, 33, 34, and 36 and the charge storage film 35 which correspond to each layer unit LU forms the one memory structure MS1 or MS2. The memory structure MS1 is provided on the side surface of the conductor film 31 which corresponds to the conductive pillar WP1. The memory structure MS2 is provided on the side surface of the conductor film 31 which corresponds to the conductive pillar WP2.

A set of the insulator films 32, 33, and 34 of each of the memory structures MS1 and MS2 functions as a block insulating film. The charge storage film 35 of each of the memory structures MS1 and MS2 functions as a floating gate. The insulator film 36 of each of the memory structures MS1 and MS2 functions as a tunnel insulating film.

The semiconductor film 37 or 38 is provided on the side surfaces of the insulator film 36 which corresponds to each layer unit LU. The semiconductor film 37 is provided on the side surface of the insulator film 36 constituting the memory structure MS1. The semiconductor film 38 is provided on the side surface of the insulator film 36 constituting the memory structure MS2. The semiconductor films 37 and 38 respectively function as the channel structures CH1 and CH2. The semiconductor films 37 and 38 contain, for example, polysilicon.

The conductor film 23 extending in the Z direction is provided on the upper surface of each of the plurality of conductor films 31. The conductor film 23 functions as the contact CV.

The conductor layer 24 is provided on the upper surface of the conductor film 23. The conductor layer 24 extends in the X direction so as to be in contact with the upper surface of each of the plurality of conductor films 23 arranged side by side in the X direction. The conductor layer 24 contains, for example, copper. The conductor layer 24 functions as the word line WL.

The insulator layer 25 is provided above the uppermost insulator layer 21 and the plurality of conductor films 31 so as to cover the conductor film 23 and the conductor layer 24. The insulator layer 25 contains, for example, silicon oxide (SiO₂).

### 1.1.4 Memory Cell Transistor

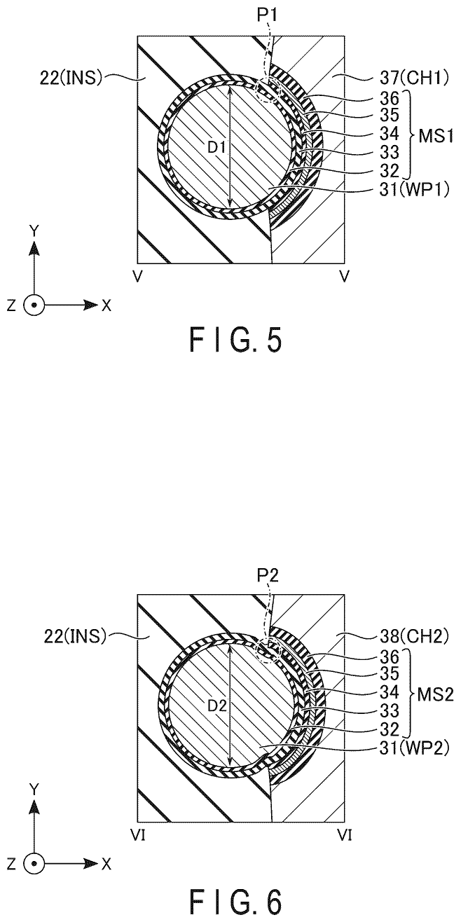

FIG. 5 is a sectional view taken along line V-V of FIG. 4, showing a first example of a sectional structure of a memory cell transistor of the memory cell array according to the first embodiment. FIG. 6 is a sectional view taken along line VI-VI of FIG. 4, showing a second example of a sectional structure of a memory cell transistor of the memory cell array according to the first embodiment. The first example corresponds to an XY section of a structure including the conductive pillar WP1, the memory structure MS1, and the channel structure CH1. The second example corresponds to an XY section of a structure including the conductive pillar WP2, the memory structure MS2, and the channel structure CH2.

As shown in FIGS. 5 and 6, when viewed in the Z direction, the insulator film 32 surrounds the conductor film 31. The insulator film 33 surrounds the insulator film 32. The insulator film 34 partially covers the insulator film 33. The insulator layer 22 covers the portion of the insulator film 33 which is not covered by the insulator film 34.

When viewed in the Z direction, the charge storage film 35 covers the insulator film 34 so as to sandwich it with the insulator film 33 in the region where the insulator layer 22 is not provided. The insulator film 36 covers the charge storage film 35 so as to sandwich it with the insulator film 34 in the region where the insulator layer 22 is not provided. The semiconductor films 37 and 38 each cover the insulator film 36 so as to sandwich it with the charge storage film 35 in the region where the insulator layer 22 is not provided.

When viewed in the Z direction, the conductor film 31 corresponding to the conductive pillar WP1 has, for example, a circular shape. Accordingly, in a boundary portion P1 between the insulator layer 22 and the memory structure MS1, the conductor film 31 corresponding to the conductive pillar WP1 maintains a substantially true circular shape.

On the other hand, when viewed in the Z direction, the conductor film 31 corresponding to the conductive pillar WP2 has a shape different from that of the conductor film 31 corresponding to the conductive pillar WP1. More specifically, the conductor film 31 corresponding to the conductive pillar WP2 has a circular shape having a recess in a boundary portion P2 between the insulator layer 22 and the memory structure MS2.

Note that a diameter D1 of the conductor film 31 corresponding to the conductive pillar WP1 in the Y direction is substantially equal to a diameter D2 of the conductor film 31 corresponding to the conductive pillar WP2 in the Y direction.

### 1.2 Manufacturing Method

FIGS. 7, 9, 11, 13, 15, 17, 19, 21, 23, 25, 27, and 29 are plan views showing an example of the planar layout of a memory device in progress according to the first embodiment. FIGS. 8, 10, 12, 14, 16, 18, 20, 22, 24, 26, 28, and 30 are sectional views showing an example of the sectional structure of the memory device in progress according to the first embodiment. The planar layout shown in each of FIGS. 7, 9, 11, 13, 15, 17, 19, 21, 23, 25, 27, and 29 corresponds to a portion including the conductive pillars WP1 and WP2 on five rows of the plan view shown in FIG. 3. The sectional view shown in each of FIGS. 8, 10, 12, 14, 16, 18, 20, 22, 24, 26, 28, and 30 corresponds to the section taken at a position corresponding to line IV IV shown in FIG. 3 in the planar layout shown in each of FIGS. 7, 9, 11, 13, 15, 17, 19, 21 23, 25, 27, and 29.

As shown in FIGS. 7 and 8, a stacked structure is formed on the upper surface of the substrate 20. More specifically, the insulator layer 21 is provided on the upper surface of the substrate 20. Subsequently, sacrificial layers 41 and insulator layers 21 are repeatedly stacked on the upper layer of the insulator layer 21 in this order. In such a stacked structure, the position at which the sacrificial layer 41 is provided is a layer corresponding to the layer unit LU (to be also simply referred to as a “layer” hereinafter). The sacrificial layer 41 contains, for example, silicon nitride (SiN).

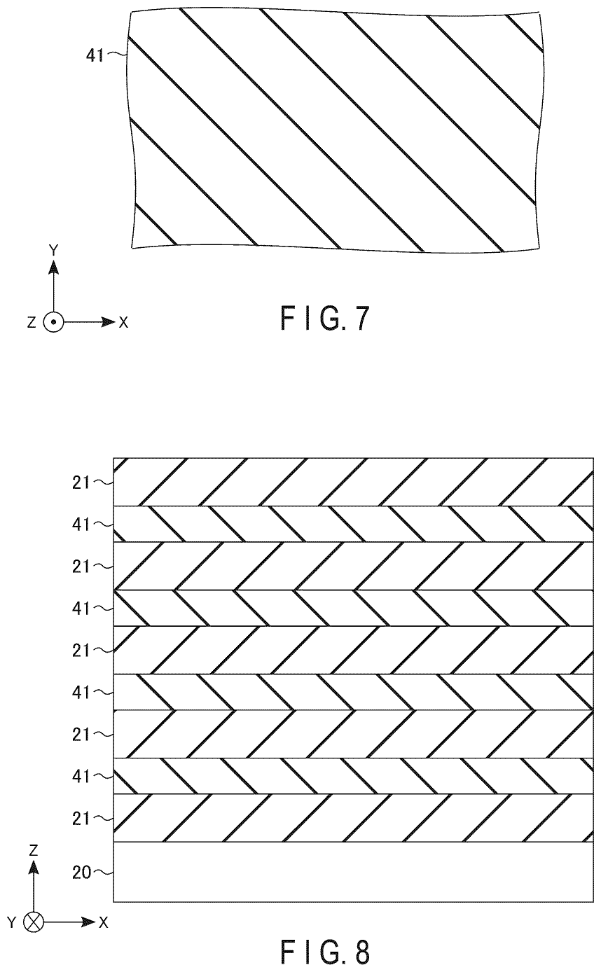

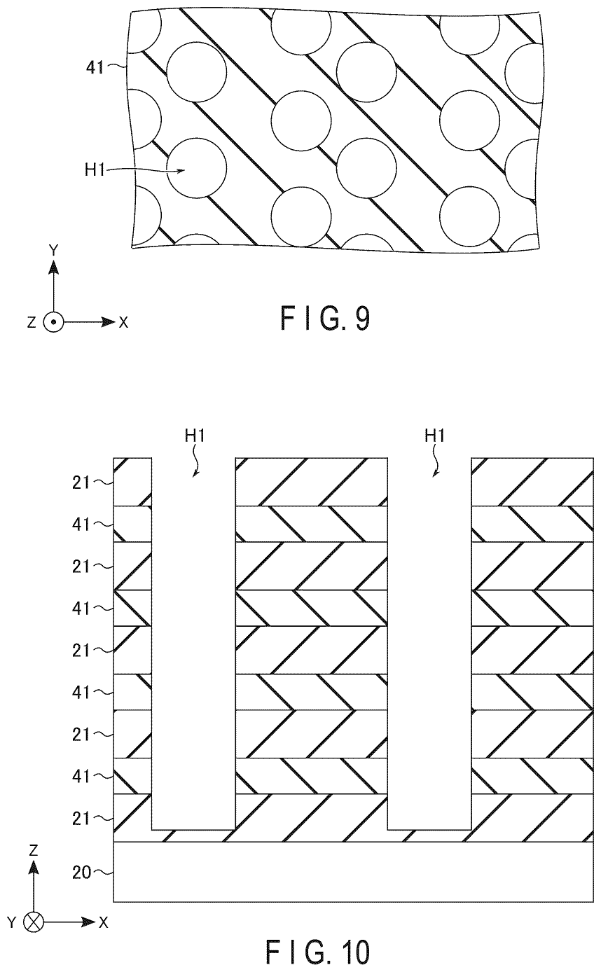

Subsequently, as shown in FIGS. 9 and 10, in the stacked structure, a plurality of holes H1 are provided in the prospective region where the plurality of conductive pillars WP1 and WP2 are provided. More specifically, the plurality of holes H1 are provided in a staggered arrangement when viewed in the Z direction. Each of the plurality of holes H1 extends through the plurality of sacrificial layers 41 and the plurality of insulator layers 21 except for the lowermost insulator layer 21. The bottom portion of each of the plurality of holes H1 reaches the lowermost insulator layer 21.

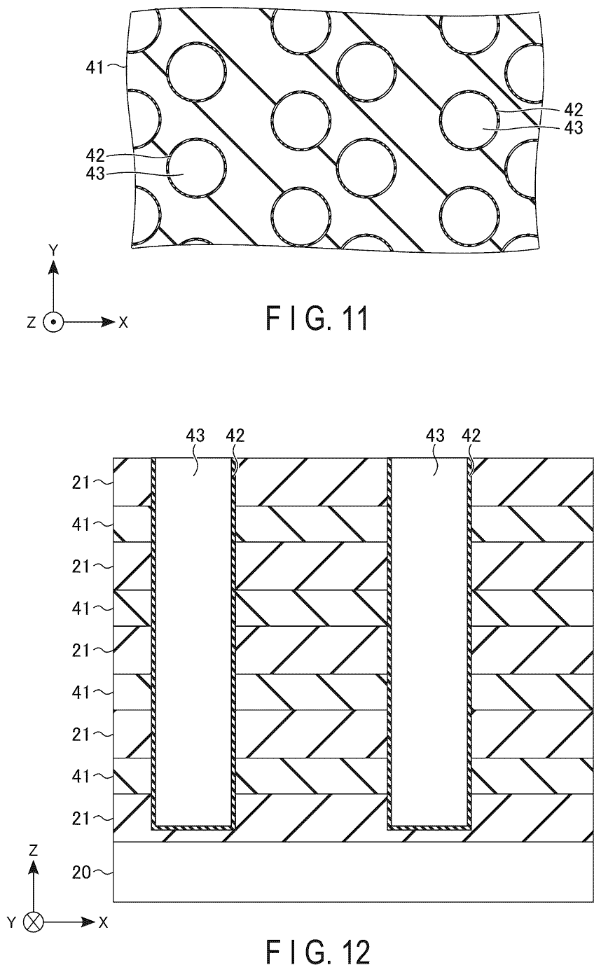

As shown in FIG. 11, and 12, each of the plurality of holes H1 is filled with a stop film 42 and a sacrificial film 43. The stop film 42 contains, for example, silicon oxide (SiO₂). The sacrificial film 43 contains, for example, polysilicon. The portions of the stop film 42 and the sacrificial film 43 which are provided above the hole H1 (that is, the upper surface of the uppermost insulator layer 21) are removed by, for example, CMP (chemical mechanical polishing).

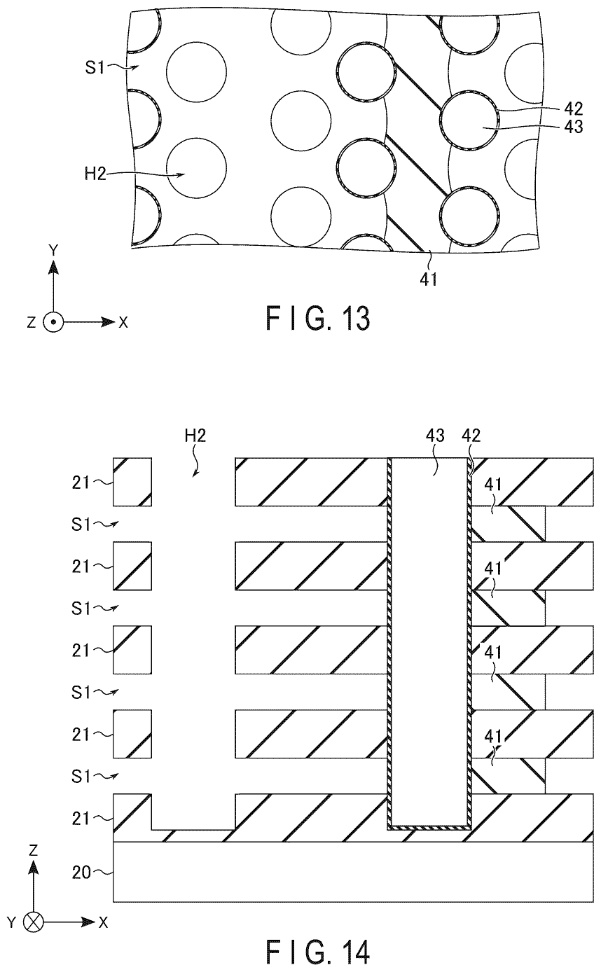

As shown in FIGS. 13 and 14, a plurality of holes H2 are provided in the prospective region of the stacked structure in which the plurality of conductive pillars WP1 are to be provided. More specifically, the sacrificial film 43 and the stop film 42 provided in the prospective region where the plurality of conductive pillars WP1 are to be provided are removed. The plurality of sacrificial layers 41 are exposed in each of the plurality of holes H2. Thereafter, each of the plurality of sacrificial layers 41 is partially removed through the plurality of holes H2. This forms a groove S1 in the prospective region, in each layer, in which the channel structure CH1 and the insulator INS are to be provided. In each layer, the sacrificial layer 41 remains in a region corresponding to the channel structure CH2.

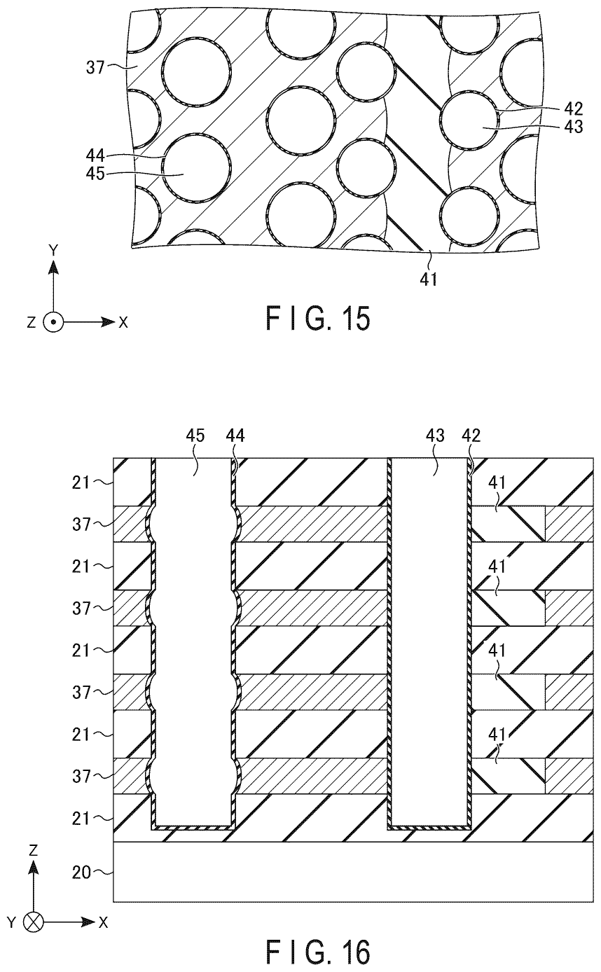

As shown in FIGS. 15 and 16, the groove S1 in each layer is filled with the semiconductor film 37. The semiconductor film 37 formed in each of the plurality of holes H2 is then etched back, and the semiconductor films 37 filling the grooves S1 in the respective layers are separated from each other. Note that the semiconductor film 37 can be formed while containing amorphous silicon.

Subsequently, each of the plurality of holes H2 is filled with a stop film 44 and a sacrificial film 45. The stop film 44 contains, for example, silicon oxide (SiO₂). The sacrificial film 45 contains, for example, polysilicon. The portions of the stop film 44 and the sacrificial film 45 which are provided above the hole H2 (that is, the upper surface of the uppermost insulator layer 21) are removed by, for example, CMP.

Note that the step of etching back the semiconductor film 37 increases the diameter of the hole H2 in each layer to a diameter larger than that of the hole H2 between the layers.

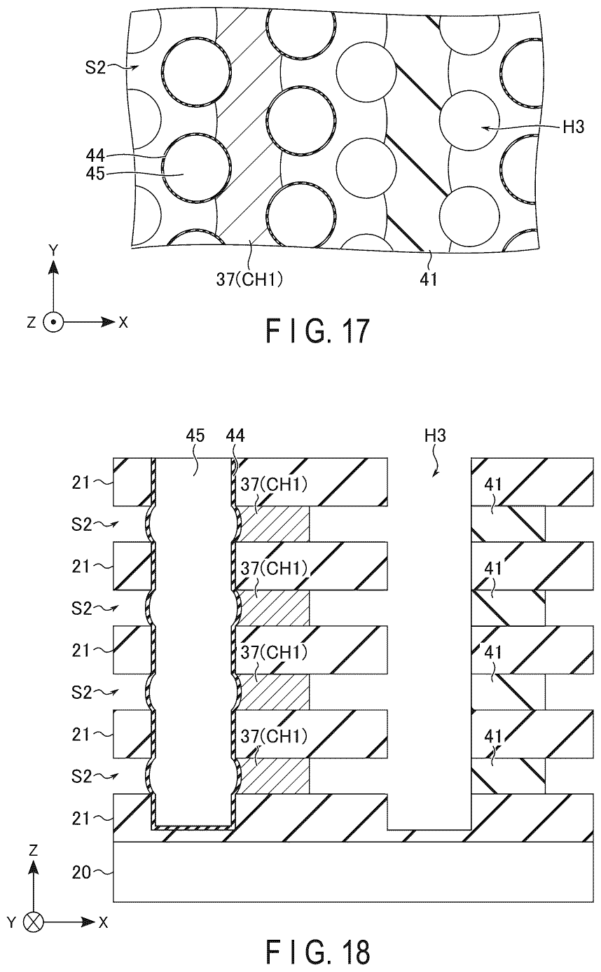

As shown in FIGS. 17 and 18, a plurality of holes H3 are provided in the prospective region, of the stacked structure, in which the plurality of conductive pillars WP2 are to be provided. More specifically, the sacrificial film 43 and the stop film 42 provided in the prospective region where the plurality of conductive pillars WP2 are to be provided are removed. This exposes the plurality of semiconductor films 37 and the plurality of sacrificial layers 41 in each of the plurality of holes H3. Thereafter, each of the plurality of semiconductor films 37 is partially removed through the plurality of holes H3. This forms a groove S2 in the prospective region in each layer in which the insulator INS is to be provided. In each layer, the semiconductor film 37 remains in the prospective region where the channel structure CH1 is to be formed.

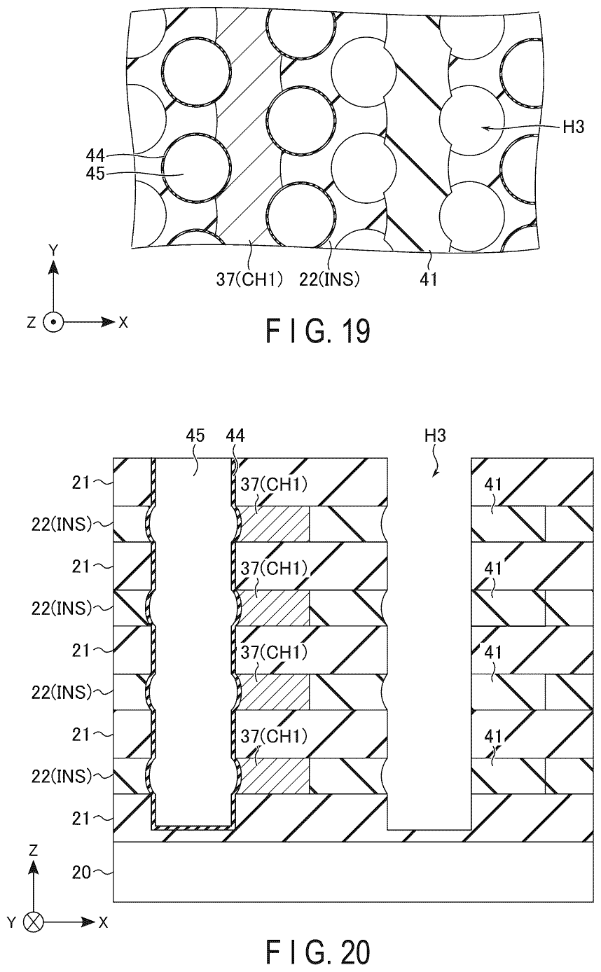

As shown in FIGS. 19 and 20, the groove S2 in each layer is filled with the insulator layer 22. The insulator layer 22 formed in each of the plurality of holes H3 is then etched back, and the insulator layers 22 filling the grooves S2 in the respective layers are separated from each other.

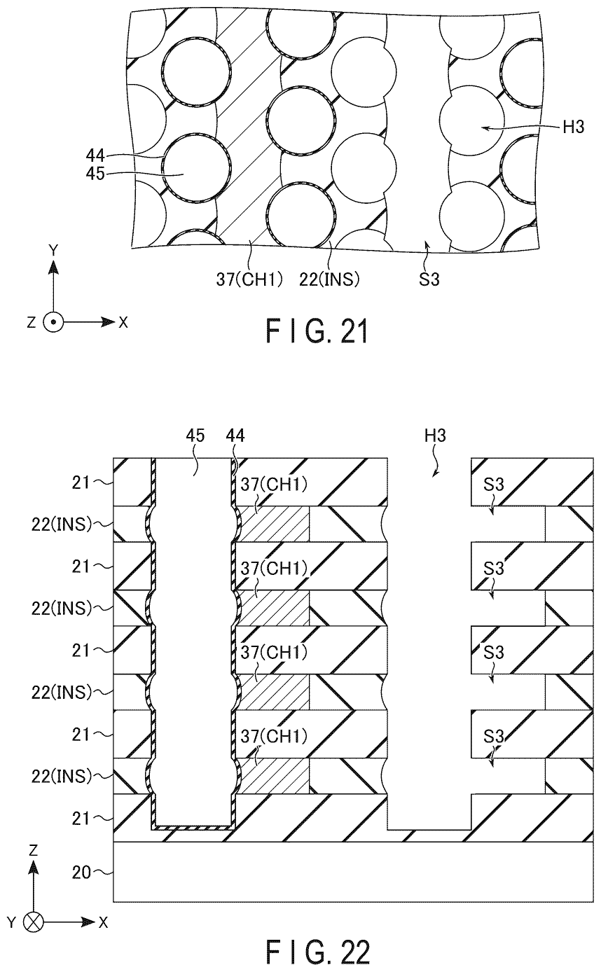

Subsequently, as shown in FIGS. 21 and 22, each of the plurality of sacrificial layers 41 is removed through the plurality of holes H3. This forms a groove S3 in the prospective region where the channel structure CH2 is to be provided in each layer.

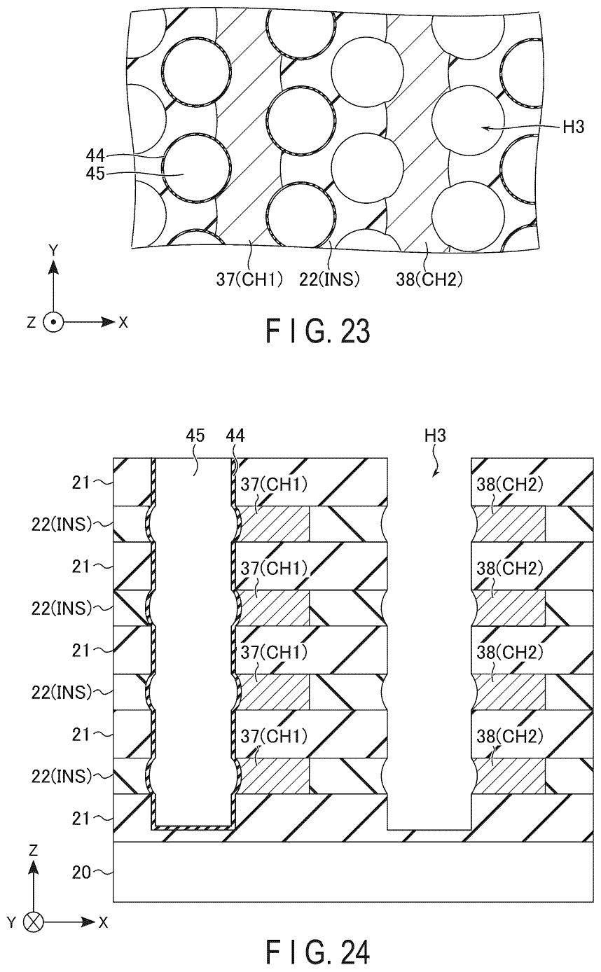

As shown in FIGS. 23 and 24, each groove S3 is filled with the semiconductor film 38. The semiconductor film 38 formed in each of the plurality of holes H3 is etched back, and the semiconductor films 38 filling the grooves S3 in the respective layers are separated from each other. The semiconductor film 38 can be formed while containing, for example, amorphous silicon.

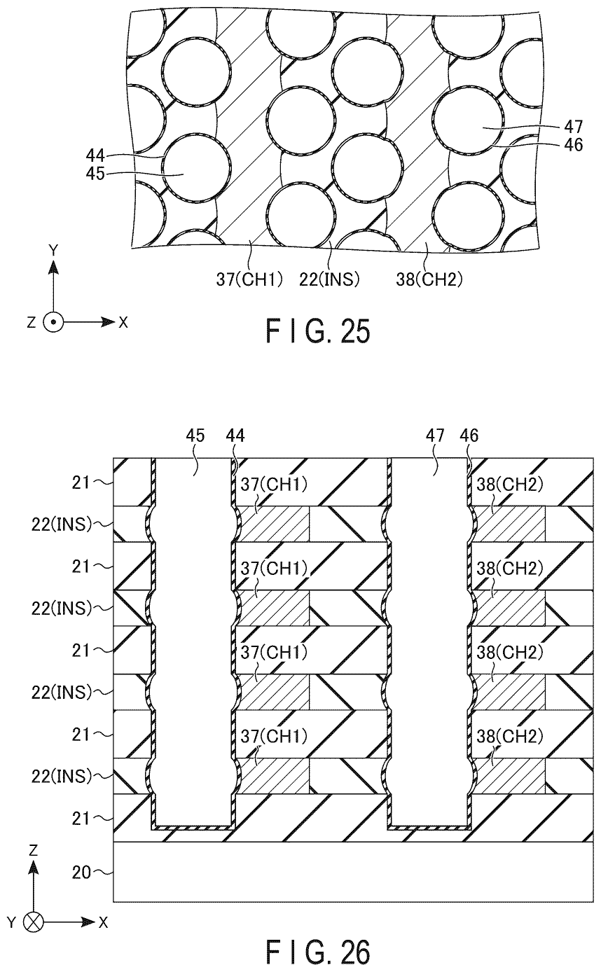

As shown in FIGS. 25 and 26, the plurality of holes H3 each are filled with a stop film 46 and a sacrificial film 47. The stop film 46 contains, for example, silicon oxide (SiO₂). The sacrificial film 47 contains, for example, polysilicon. The portions of the stop film 46 and the sacrificial film 47 which are provided above the hole H3 (that is, the upper surface of the uppermost insulator layer 21) are removed by, for example, CMP.

The step of etching back the insulator layer 22 and the semiconductor film 38 increases the diameter of the hole H3 in each layer to a diameter larger than that of the hole H between the layers.

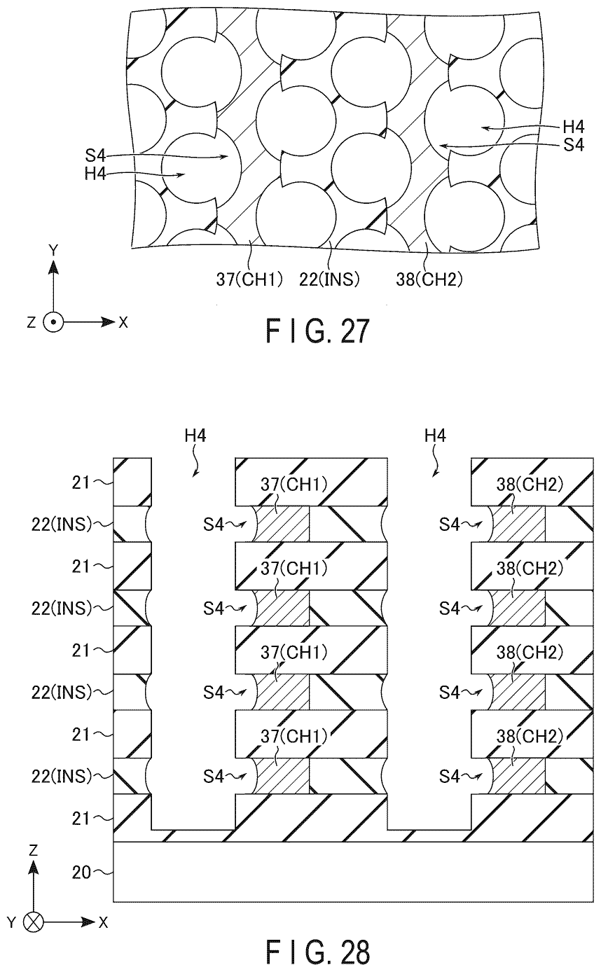

Subsequently, as shown in FIGS. 27 and 28, a plurality of holes H4 are provided in the prospective region, of the stacked structure, in which the plurality of conductive pillars WP1 and WP2 are to be provided. More specifically, the sacrificial film 45 and the stop film 44 provided in the prospective region where the plurality of conductive pillars WP1 are to be provided, and the sacrificial film 47 and the stop film 46 provided in the prospective region where the plurality of conductive pillars WP2 are to be provided are removed. The sacrificial films 45 and 47 contain the same material (for example, polysilicon) and hence are simultaneously removed by one etching process. The stop films 44 and 46 contain the same material (for example, silicon oxide) and hence are simultaneously removed by one etching process. This exposes the semiconductor film 37 in the hole H4 corresponding to the conductive pillar WP1. This also exposes the semiconductor film 38 in the hole H4 corresponding to the conductive pillar WP2.

The semiconductor films 37 and 38 are partially removed through each of the plurality of holes H4. The semiconductor films 37 and 38 contain the same material (for example, amorphous silicon) and hence are simultaneously removed by one etching process. This forms a groove S4 in the prospective region of each layer in which the memory structures MS1 and MS2 are to be provided. The residual semiconductor film 37 functions as the channel structure CH1. The residual semiconductor film 38 functions as the channel structure CH2.

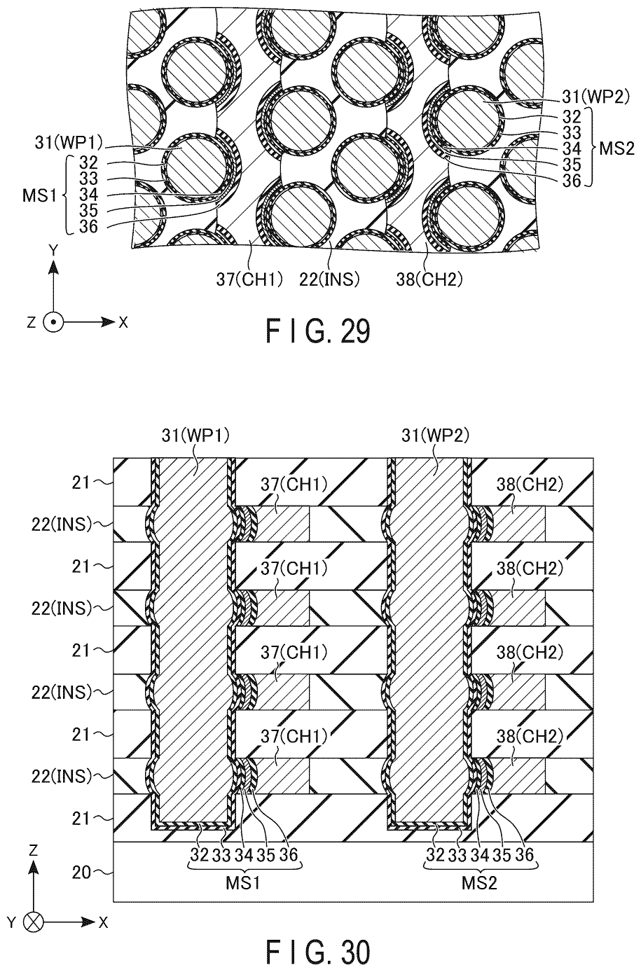

As shown in FIGS. 29 and 30, the insulator film 36, the charge storage film 35, and the insulator film 34 are formed in the groove S4 in each layer in this order. With this process, the groove S4 in each layer is filled. Note that at the time of forming the charge storage film 35, the charge storage film 35 formed in each of the plurality of holes H4 is etched back. This separates the charge storage films 35 filling the grooves S4 in the respective layers from each other. Likewise, at the time of forming the insulator film 34, the insulator film 34 formed in each of the plurality of holes H4 is etched back. This separates the insulator films 34 filling the grooves S4 in the respective layers from each other. Note that the charge storage film 35 can be formed while containing amorphous silicon.

The insulator film 33, the insulator film 32, and the conductor film 31 are formed in each of the plurality of holes H4 in this order. This fills each of the plurality of holes H4. The portions of the insulator films 33 and 32 and the conductor film 31 which are provided above the hole H4 (that is, the upper surface of the uppermost insulator layer 21) are removed by, for example, CMP.

Subsequently, structures such as the contacts CV and the word lines WL are formed above the stacked structure including the layer units LU. In addition, the amorphous silicon is crystallized into polysilicon by annealing. In the above manner, the memory device 3 is formed.

### 1.3 Effects According to First Embodiment

According to the first embodiment, a hole processed at the time of forming the memory cell array 10 is used as the conductive pillar WP1 or WP2. With this process, the pluralities of conductive pillars WP1 and WP2 are arranged in a staggered pattern in an XY plane. More specifically, the first conductive pillar WP1 corresponding to the memory cell transistor MT0 belonging to the string unit SU0 and the second conductive pillar WP2 corresponding to the memory cell transistor MT0 belonging to the string unit SU1 are arranged side by side in the X direction. The third conductive pillar WP1 corresponding to the memory cell transistor MT1 belonging to the string unit SU0 and the fourth conductive pillar WP2 corresponding to the memory cell transistor MT1 belonging to the string unit SU1 are arranged side by side in the X direction at positions shifted from those of the first conductive pillar WP1 and the second spacer layer SP2 in the Y direction. In a given layer, the channel structure CH1 is provided between the first conductive pillar WP1 and the third conductive pillar WP1. In a given layer, the channel structure CH2 is provided between the second conductive pillar WP2 and the fourth conductive pillar WP2. In a given layer, the insulator INS is provided between the second conductive pillar WP2 and the third conductive pillar WP1. The third conductive pillar WP1 is located between the first conductive pillar WP1 and the second conductive pillar WP2 in the X direction. The second conductive pillar WP2 is located between the third conductive pillar WP1 and the fourth conductive pillar WP2 in the X direction. Accordingly, the memory structures MS1 and MS2 arranged in correspondence with the conductive pillars WP1 and WP2 can also be arranged in a staggered pattern. This can reduce the area occupied by one memory cell.

Furthermore, at the time of forming the channel structure CH1, after the groove S1 is filled with the semiconductor film 37, the semiconductor film 37 in the hole H2 is etched back. This increases the diameter of the hole H2 in each layer. At the time of forming the insulator INS, after the groove S2 is filled with the insulator layer 22, the insulator layer 22 in the hole H3 is etched back. This increases the diameter of the hole H3 in each layer. However, according to the first embodiment, for example, no holes are formed, which are used for material preplacement processing but are not used as the conductive pillars WP1 and WP2. This makes it possible to reduce the area occupied by one memory cell as compared with the case where holes which are not used as the conductive pillars WP1 and WP2 are formed.

In contrast to the case where the diameter of the hole H2 is increased in all directions when viewed in the Z direction, the diameter of the hole H3 is increased only in a direction toward the insulator INS. For this reason, the conductive pillar WP1 and the conductive pillar WP2 have different shapes when viewed in the Z direction.

### 2. Second Embodiment

A memory device according to the second embodiment will be described next. The second embodiment differs from the first embodiment in that it suppresses increases in the diameters of conductive pillars WP1 and WP2 in a manufacturing process. The second embodiment will be described below, focusing on configurations and manufacturing methods different from those of the first embodiment. Descriptions of configurations and manufacturing methods similar to those of the first embodiment will be omitted as appropriate.

### 2.1 Configuration

### 2.1.1 Memory Cell Array

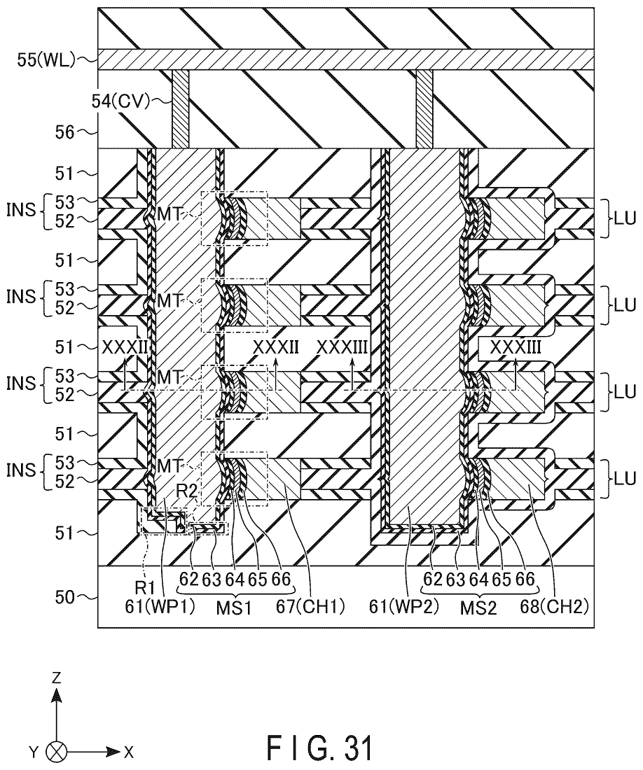

FIG. 31 is a sectional view showing an example of the sectional structure of a memory cell array according to the second embodiment. FIG. 31 corresponds to FIG. 4 in the first embodiment.

As shown in FIG. 31, a memory cell array 10 includes a substrate 50, insulator layers 51 and 56, conductor films 54 and 61, a conductor layer 55, insulator films 52, 53, 62, 63, 64, and 66, a charge storage film 65, and semiconductor films 67 and 68.

The substrate 50 is a semiconductor substrate containing, for example, silicon.

The plurality of insulator layers 51 are provided above the substrate 50 so as to be separated from each other in the Z direction. The semiconductor film 51 contains, for example, silicon oxide (SiO₂).

The insulator films 52 and 53 are provided between the semiconductor films 51 adjacent to each other in the Z direction. The insulator films 52 and 53 contain, for example, different oxide film types. The insulator films 52 and 53 function as insulators INS. A layer unit LU is provided on the layer on which the insulator films 52 and 53 are provided. In the example shown in FIG. 31, the four layer units LU are stacked.

The plurality of conductor films 61 are conductors extending through the semiconductor film 51 and insulator films 52 and 53 in the Z direction. The lower end of each of the plurality of conductor films 61 is located in the lowermost insulator layer 51. The upper end of each of the plurality of conductor films 61 is located at the same height as the upper surface of the uppermost insulator layer 51. The insulator film 61 functions as a conductive pillar WP1 or WP2. The insulator film 61 contains, for example, titanium nitride (TiN).

The insulator film 62 is provided so as to cover the side surfaces and the lower surface of the insulator film 61. The insulator film 62 contains, for example, aluminum oxide (AlO).

The insulator film 63 is provided so as to cover the side surfaces and the lower surface of the insulator film 62. The insulator film 63 contains, for example, silicon oxide (SiO₂).

The insulator film 64 is provided on the portion of the side surfaces of the insulator film 63 which corresponds to the layer unit LU. The insulator films 64 corresponding to the respective layer units LU are separated from each other. The insulator film 64 contains, for example, hafnium silicate (HfSiO).

The charge storage film 65 is provided on the side surface of the insulator film 64 which corresponds to each layer unit LU. The charge storage film 65 contains, for example, polysilicon.

The insulator film 66 is provided on the side surface of the charge storage film 65 which corresponds to each layer unit LU. The insulator film 66 contains, for example, silicon oxide (SiO₂).

In the above configuration, a set of the insulator films 62, 63, 64, and 66 and the charge storage film 65 which correspond to each layer unit LU forms one memory structure MS1 or MS2. The memory structure MS1 is provided on the side surface of the insulator film 61 which corresponds to the conductive pillar WP1. The memory structure MS2 is provided on the side surface of the insulator film 61 which corresponds to the conductive pillar WP2.

A set of the insulator films 62, 63, and 64 of each of the memory structures MS1 and MS2 functions as a block insulating film. The charge storage film 65 of each of the memory structures MS1 and MS2 functions as a floating gate. The insulator film 66 of each of the memory structures MS1 and MS2 functions as a tunnel insulating film.

The semiconductor film 67 or 68 is provided on the side surface of the insulator film 66 which corresponds to each layer unit LU. The semiconductor film 67 is provided on the side surface of the insulator film 66 constituting the memory structure MS1. The semiconductor film 68 is provided on the side surface of the insulator film 66 constituting the memory structure MS2. The semiconductor films 67 and 68 respectively function as channel structures CH1 and CH2. The semiconductor films 67 and 68 contain, for example, polysilicon.

The conductor film 54 extending in the Z direction is provided on the upper surface of each of the plurality of conductor films 61. The conductor film 54 functions as a contact CV.

The conductor layer 55 is provided on the upper surface of the conductor film 54. The conductor layer 55 extends in the X direction so as to be in contact with the upper surface of each of the plurality of conductor films 54 arranged side by side in the X direction. The conductor layer 55 contains, for example, copper. The conductor layer 55 functions as a word line WL.

The insulator layer 56 is provided above the uppermost insulator layer 51 and the plurality of conductor films 61 so as to cover the conductor film 54 and the conductor layer 55. The insulator layer 56 contains, for example, silicon oxide (SiO₂).

### 2.1.2 Memory Cell Transistor

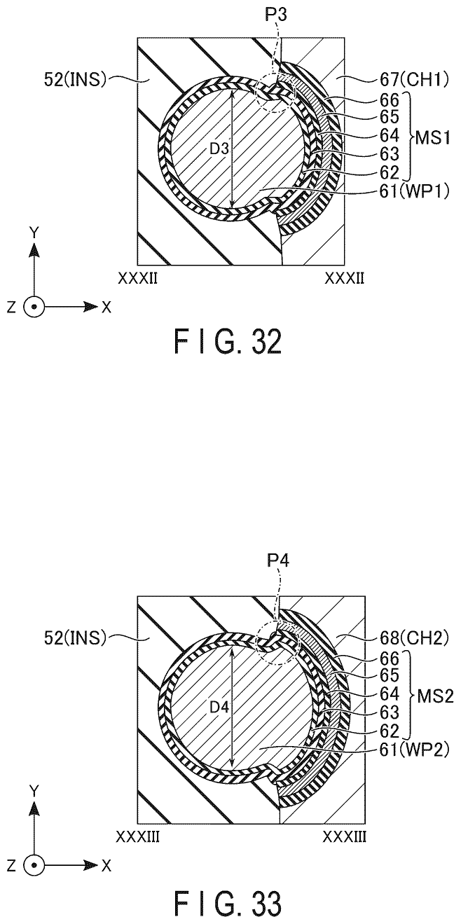

FIG. 32 is a sectional view taken along line XXXII XXXII of FIG. 31, showing the first example of the sectional structure of a memory cell transistor of the memory cell array according to the second embodiment. FIG. 33 is a sectional view taken along line XXXIII XXXIII of FIG. 31, showing the second example of the sectional structure of a memory cell transistor of the memory cell array according to the second embodiment. The first example corresponds to an XY section of a structure including the conductive pillar WP1, the memory structure MS1, and the channel structure CH1. The second example corresponds to an XY section of a structure including the conductive pillar WP2, the memory structure MS2, and the channel structure CH2.

As shown in FIGS. 32 and 33, when viewed in the Z direction, the insulator film 62 surrounds the conductor film 61. The insulator film 63 surrounds the insulator film 62. The insulator film 64 partially covers the insulator film 63. The insulator film 52 covers the portion of the insulator film 63 which is not covered by the insulator film 64.

When viewed in the Z direction, the charge storage film 65 covers the insulator film 64 so as to sandwich it with the insulator film 63 in the region where the insulator film 52 is not provided. The insulator film 66 covers the charge storage film 65 so as to sandwich it with the insulator film 64 in the region where the insulator film 52 is not provided. Each of the semiconductor films 67 and 68 covers the insulator film 66 so as to sandwich it with the charge storage film 65 in the region where the insulator film 52 is not provided.

When viewed in the Z direction, the conductor film 61 corresponding to the conductive pillar WP1 has a distorted circular shape in a boundary portion P3 between the insulator film 52 and the memory structure MS1. Likewise, the conductor film 61 corresponding to the conductive pillar WP2 has a distorted circular shape in a boundary portion P4 between the insulator film 62 and the memory structure MS2.

Note that a diameter D3 of the conductor film 61 corresponding to the conductive pillar WP1 in the Y direction can be smaller than a diameter D4 of the conductor film 61 corresponding to the conductive pillar WP2 in the Y direction. The diameters D3 and D4 according to the second embodiment are smaller than the diameters D1 and D2 according to the first embodiment.

### 2.1.3 Conductive Pillars WP1 and WP2 and Insulator INS

The configurations of the conductive pillars WP1 and WP2 and the insulator INS in the memory cell array according to the second embodiment will be described again with reference to FIG. 31.

The conductor film 61 functioning as the conductive pillar WP1 has a shape different from that of the conductor film 61 functioning as the conductive pillar WP2. The conductor film 61 functioning as the conductive pillar WP1 includes a portion R1 that is relatively shallow in the Z direction at the lower end and a portion R2 that is relatively deep. That is, the portions R1 and R2 form a stepped portion at the lower end of the conductor film 61 functioning as the conductive pillar WP1. The portion R1 is located on the opposite side to the memory structure MS1 with respect to the portion R2. The insulator film 53 is provided between the insulator layer 51 and the stacked film of the insulator films 62 and 63 covering the portion R1. On the other hand, the stacked film of the insulator films 62 and 63 covering the portion R2 is in contact with the insulator layer 51.

The conductor film 61 functioning as the conductive pillar WP2 has a substantially flat lower end. That is, the lower end of the conductor film 61 functioning as the conductive pillar WP2 has no stepped portion. The insulator film 52 is provided between the insulator layer 51 and the lower end of the conductor film 61 functioning as the conductive pillar WP2.

The insulator film 52 covers the set of the conductor film 61 functioning as the conductive pillar WP2, the memory structure MS2, and the channel structure CH2. The insulator film 53 covers the portion R1 of the conductor film 61 functioning as the conductive pillar WP1. The insulator film 53 is also provided between the insulator layer 51 and a portion of the insulator film 52 except for a portion covering the set of the conductor film 61 functioning as the conductive pillar WP2, the memory structure MS2, and the channel structure CH2.

### 2.2 Manufacturing Method

FIGS. 34, 36, 38, 40, 42, 44, 46, 48, 50, 52, 54, 56, 58, 60, and 62 are plan views showing an example of the planar layout of the memory device in progress according to the second embodiment. FIGS. 35, 37, 39, 41, 43, 45, 47, 49, 51, 53, 55, 57, 59, 61, and 63 are sectional views showing an example of the sectional structure of the memory device in progress according to the second embodiment. The planar layout shown in each of FIGS. 34, 36, 38, 40, 42, 44, 46, 48, 50, 52, 54, 56, 58, 60, and 62 corresponds to the portion of the plane shown in FIG. 3 which corresponds to a portion including the conductive pillars WP1 and WP2 on five rows. The sectional views shown in FIGS. 35, 37, 39, 41, 43, 45, 47, 49, 51, 53, 55, 57, 59, 61, and 63 each correspond to the section taken at the same position as line IV-IV shown in FIG. 3 in the planar layout shown in FIGS. 34, 36, 38, 40, 42, 44, 46, 48, 50, 52, 54, 56, 58, 60, and 62.

First of all, as shown in FIGS. 34 and 35, a stacked structure is formed on the upper surface of the substrate 50. More specifically, the insulator layer 51 is provided on the upper surface of the substrate 50. Subsequently, sacrificial layers 71 and insulator layers 51 are repeatedly stacked on the upper surface of the insulator layer 51 in this order. In this stacked structure, the position at which the sacrificial layer 71 is provided is a layer corresponding to the layer unit LU. The sacrificial layer 71 contains, for example, silicon nitride (SiN).

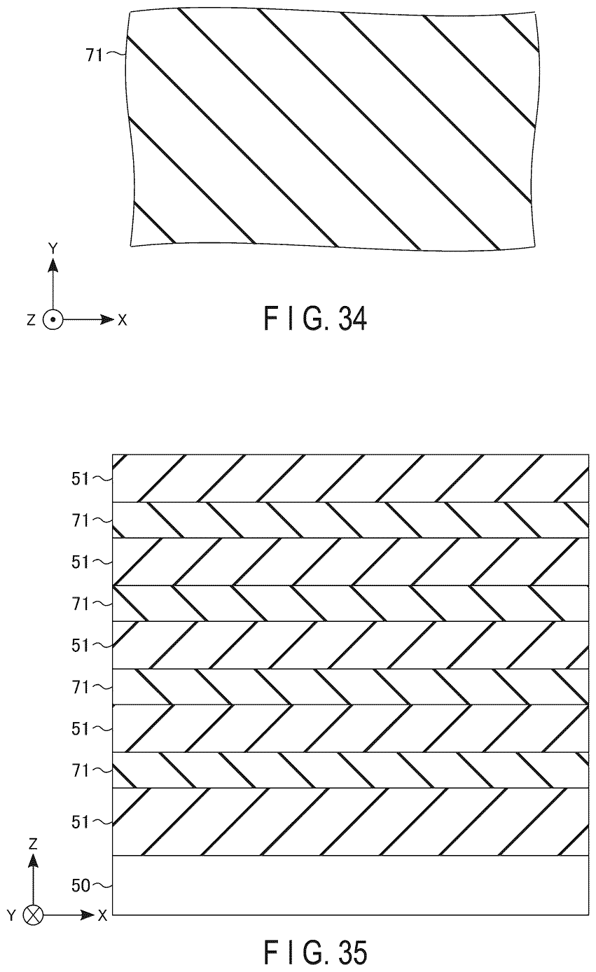

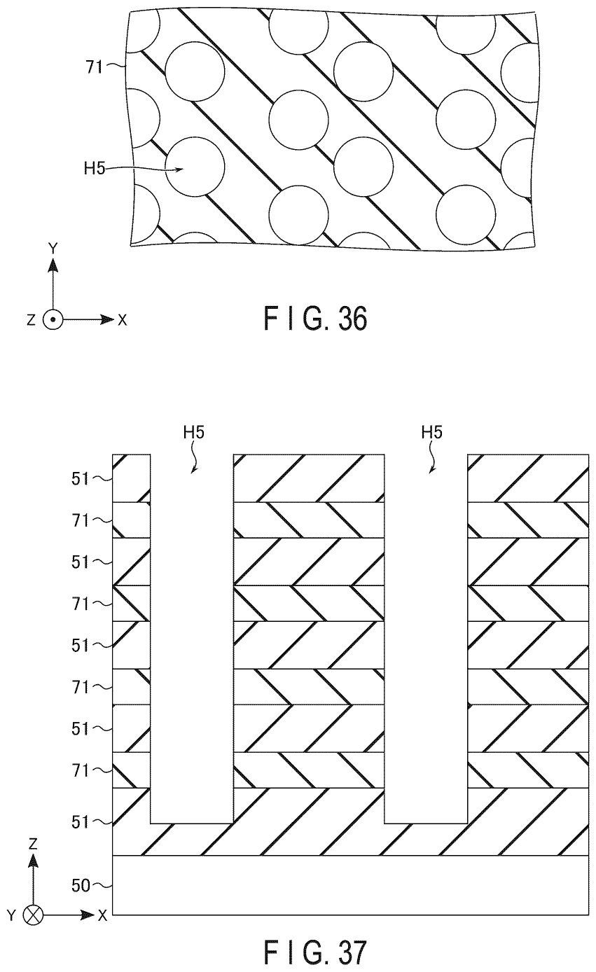

Subsequently, as shown in FIGS. 36 and 37, in the stacked structure, a plurality of holes H5 are provided in prospective region where the plurality of conductive pillars WP1 and WP2 are to be provided. More specifically, the plurality of holes H5 are arranged in a staggered pattern when viewed in the Z direction. Each of the plurality of holes H5 extends through the plurality of sacrificial layers 71 and the plurality of insulator layers 51 except for the lowermost insulator layer 51. The bottom portion of each of the plurality of holes H5 reaches the lowermost insulator layer 51.

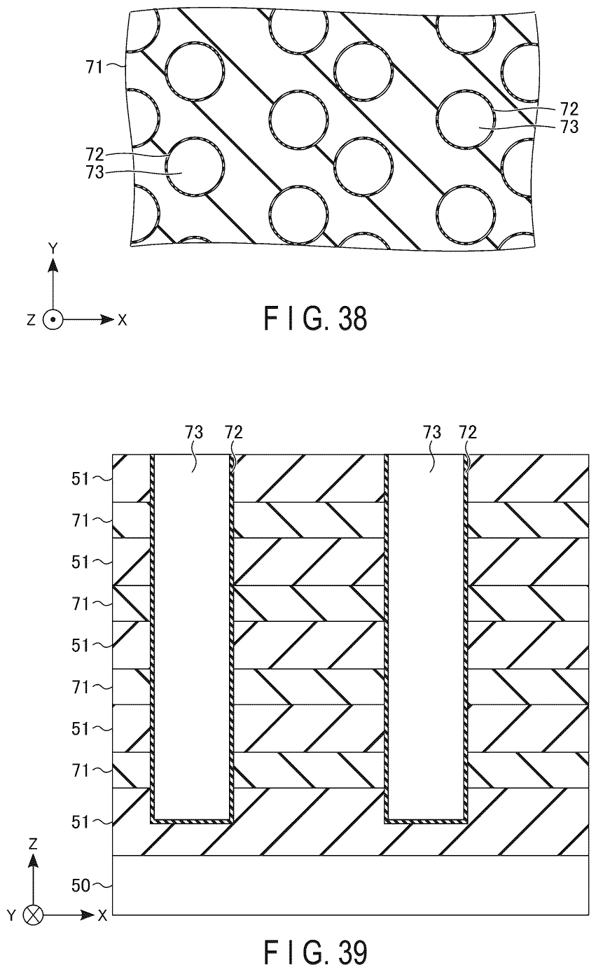

As shown in FIGS. 38 and 39, each of the plurality of holes H5 is filled with a stop film 72 and a sacrificial film 73. The stop film 72 contains, for example, silicon oxide (SiO₂). The sacrificial film 73 contains, for example, polysilicon. The portions of the stop film 72 and the sacrificial film 73 which are provided above the hole H5 (that is, the upper surface of the uppermost insulator layer 51) are removed by, for example, CMP.

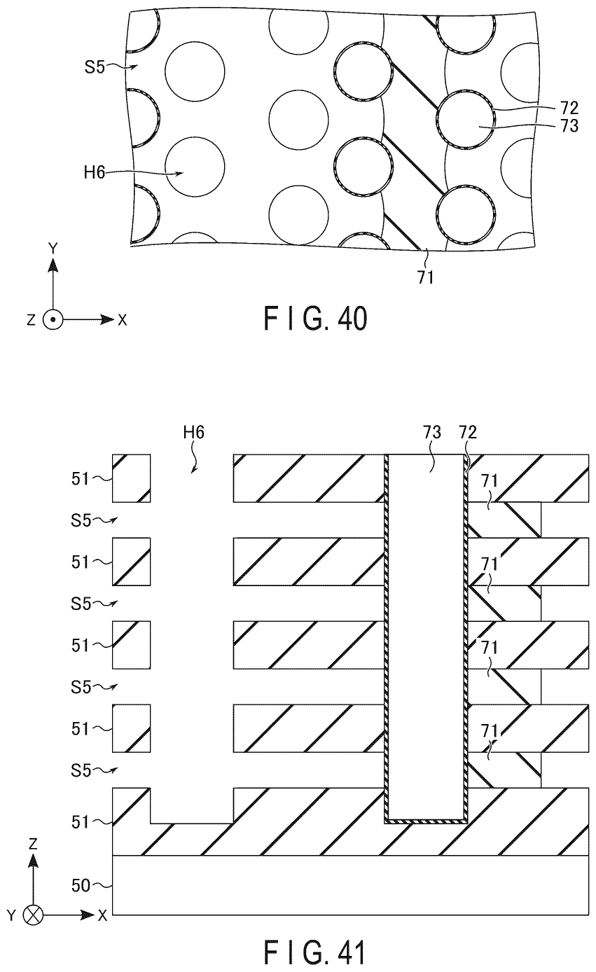

As shown in FIGS. 40 and 41, in the stacked structure, a plurality of holes H6 are provided in the prospective region where the plurality of conductive pillars WP1 are provided. More specifically, the sacrificial film 73 and the stop film 72 provided in the prospective region where the plurality of conductive pillars WP1 are to be provided are removed. With this process, the plurality of sacrificial layers 71 are exposed in each of the plurality of holes H6. Thereafter, each of the plurality of sacrificial layers 71 is partially removed through the plurality of holes H6. This forms a groove S5 in the prospective region where the channel structure CH1 and the insulator INS are to be provided in each layer. In each layer, the sacrificial layer 71 remains in a region corresponding to the channel structure CH2.

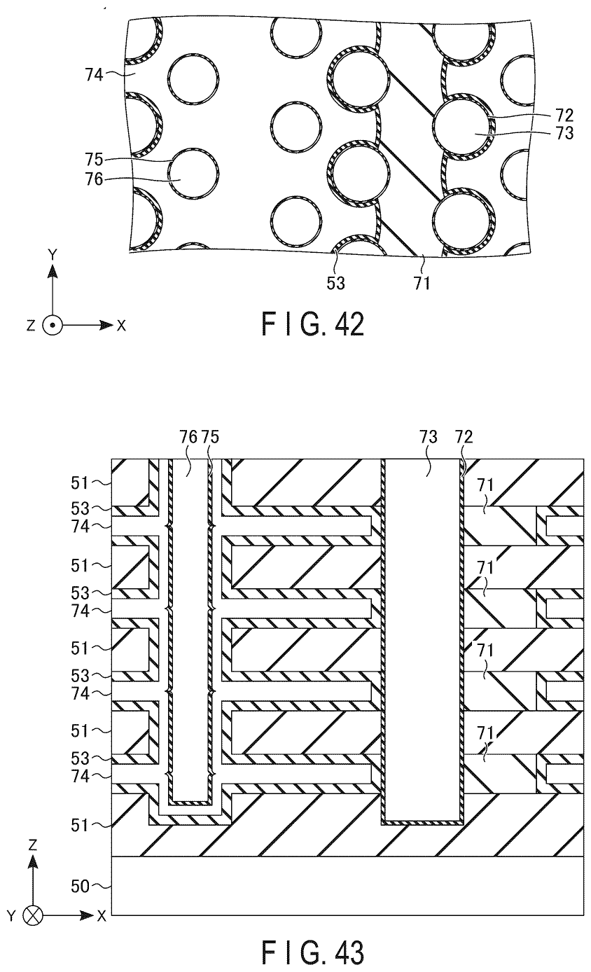

As shown in FIGS. 42 and 43, the groove S5 in each layer is filled with an insulator film 53 and a sacrificial film 74. The insulator film 53 and the sacrificial film 74 formed in each of the holes H6 remain without being etched back. The sacrificial film 74 contains, for example, amorphous silicon.

Subsequently, each of the plurality of holes H6 is filled with a stop film 75 and a sacrificial film 76. The stop film 75 contains, for example, silicon oxide (SiO₂). The sacrificial film 76 contains, for example, polysilicon. The portions of the insulator film 53, the sacrificial film 74, the stop film 75, and the sacrificial film 76 which are provided above the hole H6 (that is, the upper surface of the uppermost insulator layer 51) are removed by, for example, CMP.

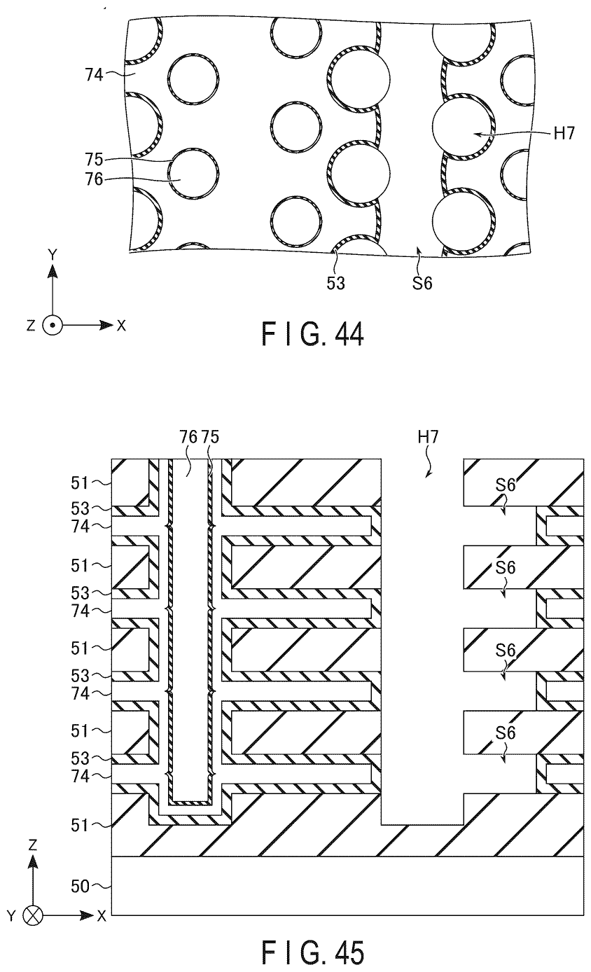

As shown in FIGS. 44 and 45, in the stacked structure, a plurality of holes H7 are provided in the prospective region where the plurality of conductive pillars WP2 are to be provided. More specifically, the sacrificial film 73 and the stop film 72 provided in the prospective regions where the plurality of conductive pillars WP2 are to be provided are removed. With this process, the plurality of sacrificial layers 71 are exposed in each of the plurality of holes H7. Thereafter, each of the plurality of sacrificial layers 71 is removed through the plurality of holes H7. This forms a groove S6 in the prospective region where the channel structure CH2 is to be provided. The insulator film 53 is exposed in each of the pluralities of holes H7 and grooves S6.

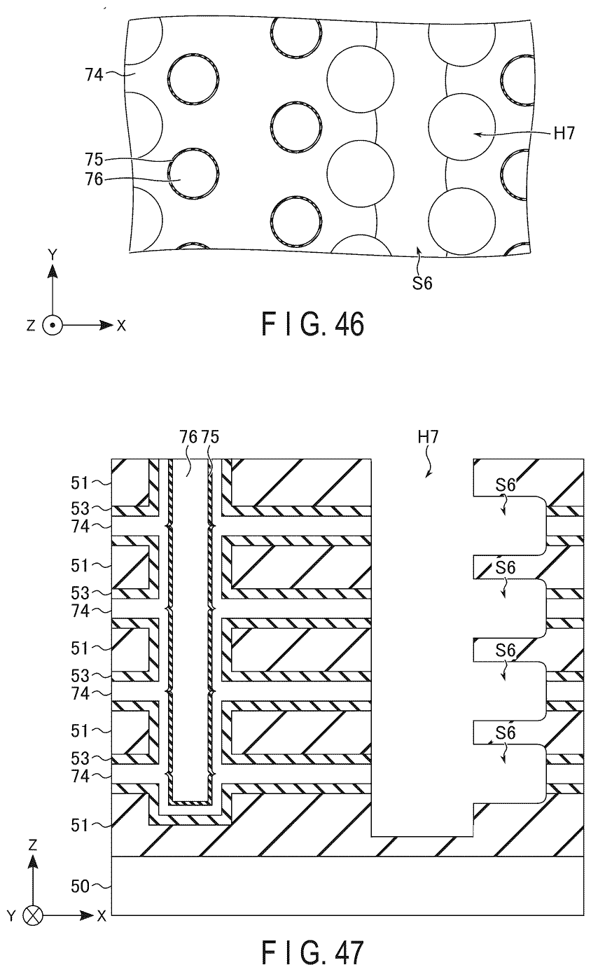

As shown in FIGS. 46 and 47, the insulator layer 51 and the insulator film 53 are partially removed through each of the pluralities of holes H7 and grooves S6. This increases the diameter of the hold H7 and also increases the size of the groove S6 in the Z direction.

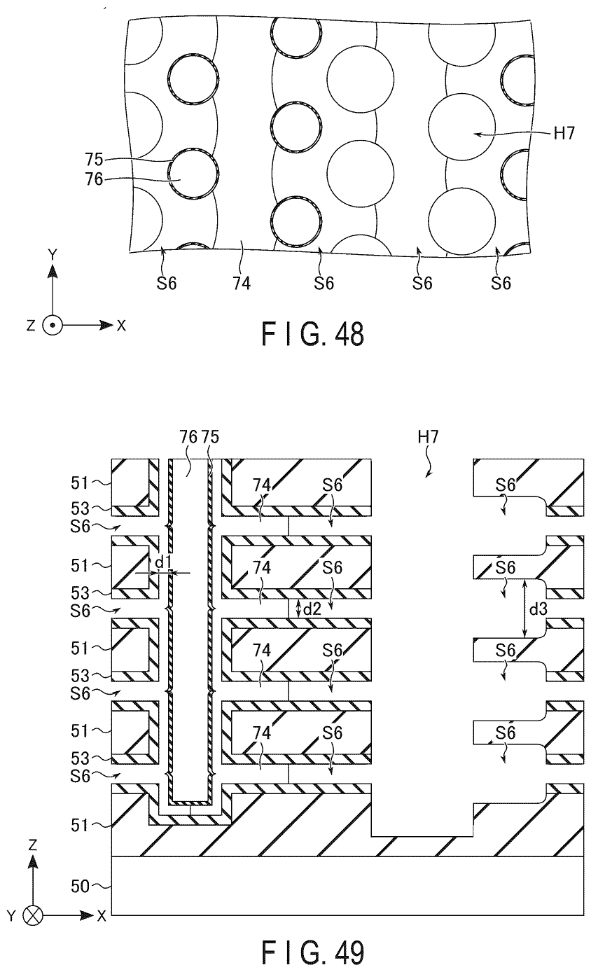

As shown in FIGS. 48 and 49, the sacrificial film 74 is partially removed through each of the pluralities of holes H7 and grooves S6. With this process, in each layer, the groove S6 expands to the prospective region where the insulator INS is to be provided and the prospective region where the portion R1 of the conductive pillar WP1 is to be provided. In addition, the grooves S6 in the respective layers communicate with each other through the side surfaces of the stop films 75. In each layer, the sacrificial film 74 remains in a region corresponding to the channel structure CH1 and the prospective region where the portion R2 of the conductive pillar WP1 is to be provided.

In this case, the groove S6 is classified into three types of portions in accordance with the magnitudes of widths. The first type of portion is the portion of the groove S6 which is formed between the stop film 75 and the insulator film 52 and has a width d1. The second type of portion is a portion which is formed so as to be sandwiched between the insulator films 52 between the adjacent insulator layers 51 and has a width d2. The third type of portion is a portion which is formed without being sandwiched between the insulator films 52 between the adjacent insulator layers 51 and has a width d3. The width d2 is equal to or more than the width d1 and is smaller than the width d3.

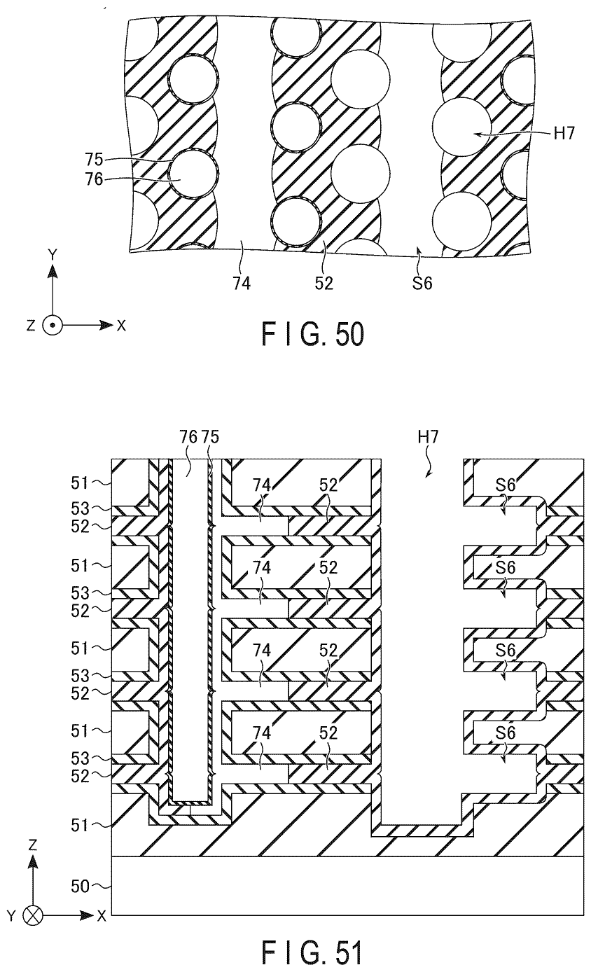

As shown in FIGS. 50 and 51, the portions of the groove S6 which respectively have the width d1 and the width d2 are filled with the insulator films 52. The insulator films 52 are respectively formed in the portion of the groove S6 which has the width d3 and in the hole H7. The insulator film 52 formed in each of the plurality of holes H7 remains without being etched back.

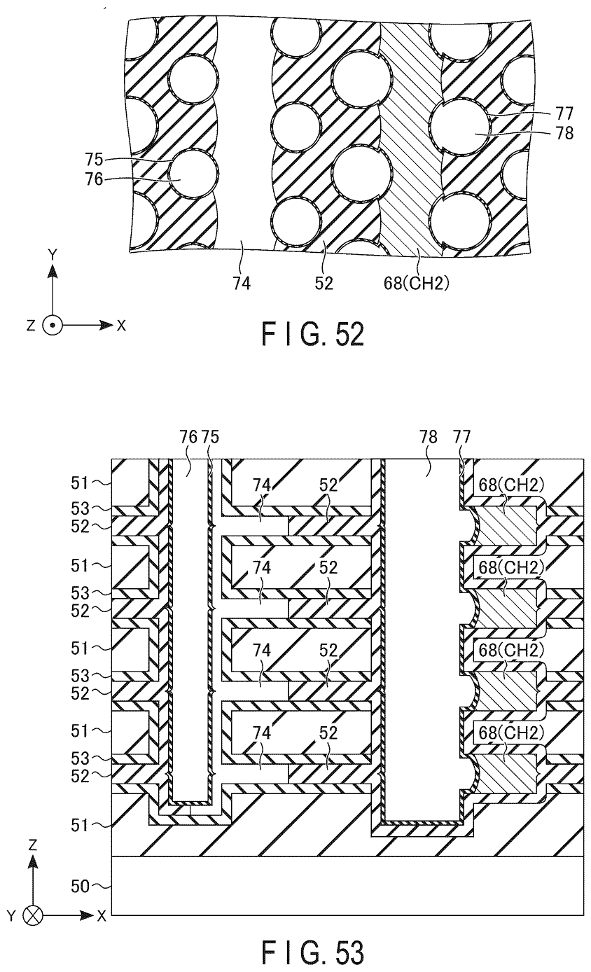

As shown in FIGS. 52 and 53, the inside of the groove S6 which remains after the formation of the insulator film 52 is filled with the semiconductor film 68. The semiconductor film 68 formed in each of the plurality of holes H7 is etched back, and the semiconductor films 68 filling the grooves S6 in the respective layers are separated from each other.

Subsequently, each of the plurality of holes H7 is filled with a stop film 77 and a sacrificial film 78. The stop film 77 contains, for example, silicon oxide (SiO₂). The sacrificial film 78 contains, for example, polysilicon. The portions of the stop film 77 and sacrificial film 78 which are provided above the hole H7 (that is, the upper surface of the uppermost insulator layer 51) are removed by, for example, CMP.

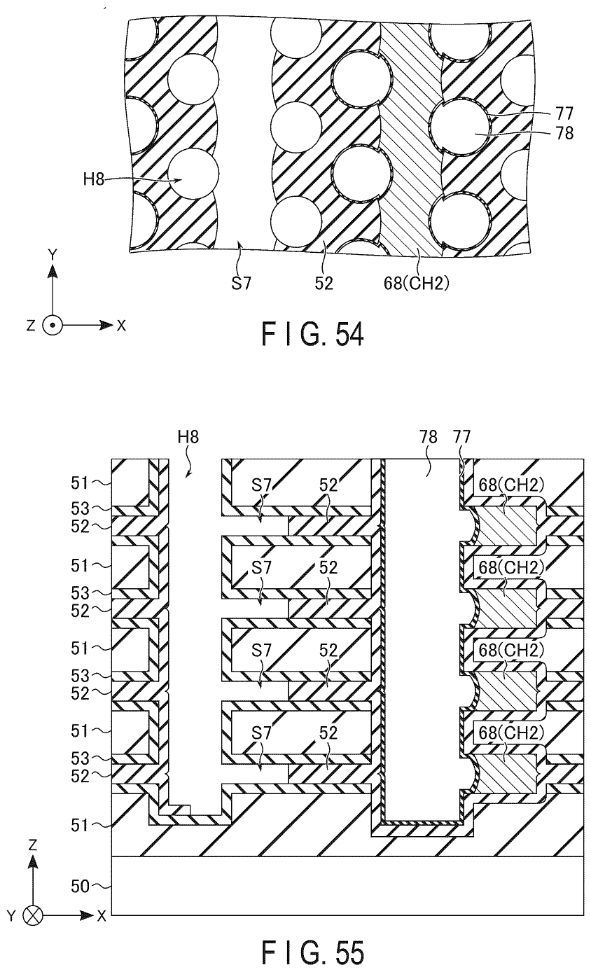

As shown in FIGS. 54 and 55, in the stacked structure, a plurality of holes H8 are provided in the prospective region where the plurality of conductive pillars WP1 are to be provided. More specifically, the sacrificial film 76 and the stop film 75 provided in the prospective region where the plurality of conductive pillars WP1 are to be provided are removed. With this process, the sacrificial film 74 is exposed in each of the plurality of holes H8. Thereafter, the sacrificial film 74 is removed through the plurality of holes H8. This forms the groove S7 in the prospective region where the channel structure CH1 is to be provided in each layer. The insulator films 52 and 53 are exposed in each of the pluralities of holes H8 and grooves S7.

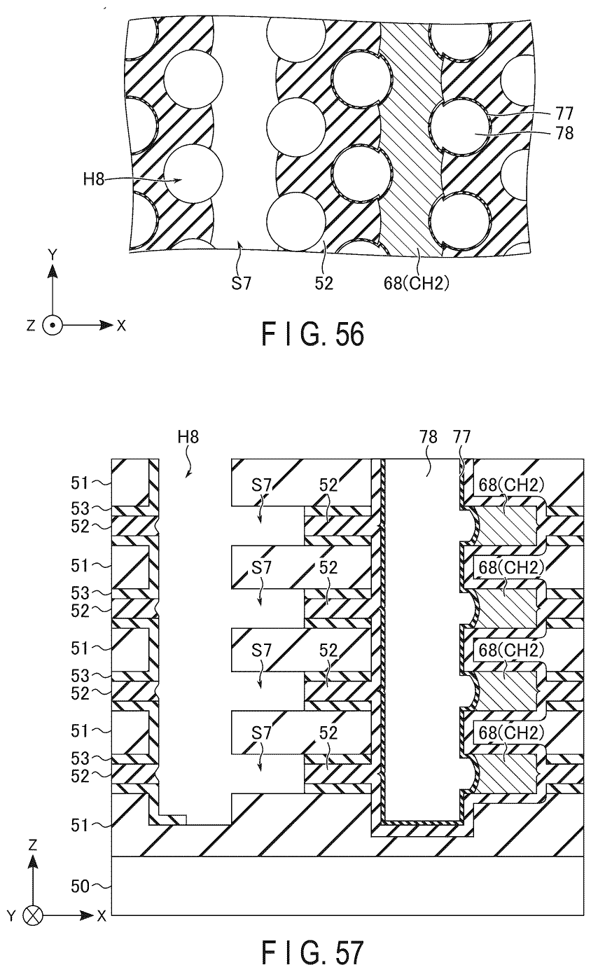

As shown in FIGS. 56 and 57, the insulator films 52 and 53 are partially removed through each of the pluralities of holes H8 and grooves S7. This increases the diameter of the hole H8 and also increases the size of the groove S7 in the Z direction.

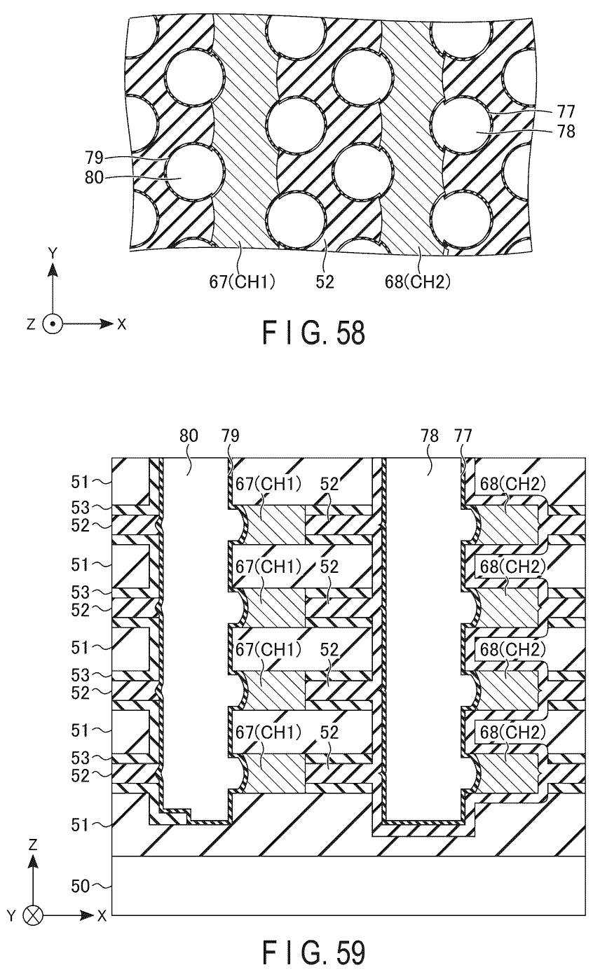

As shown in FIGS. 58 and 59, in each layer, the groove S7 is filled with the semiconductor film 67. The semiconductor film 67 formed in each of the plurality of holes H8 is etched back, and the semiconductor films 67 filling the grooves S7 in the respective layers are separated from each other.

Subsequently, each of the plurality of holes H8 is filled with a stop film 79 and a sacrificial film 80. The stop film 79 contains, for example, silicon oxide (SiO₂). The sacrificial film 80 contains, for example, polysilicon. The portions of the stop film 79 and the sacrificial film 80 which are located above the hole H8 (that is, the upper surface of the uppermost insulator layer 51) are removed by, for example, CMP.

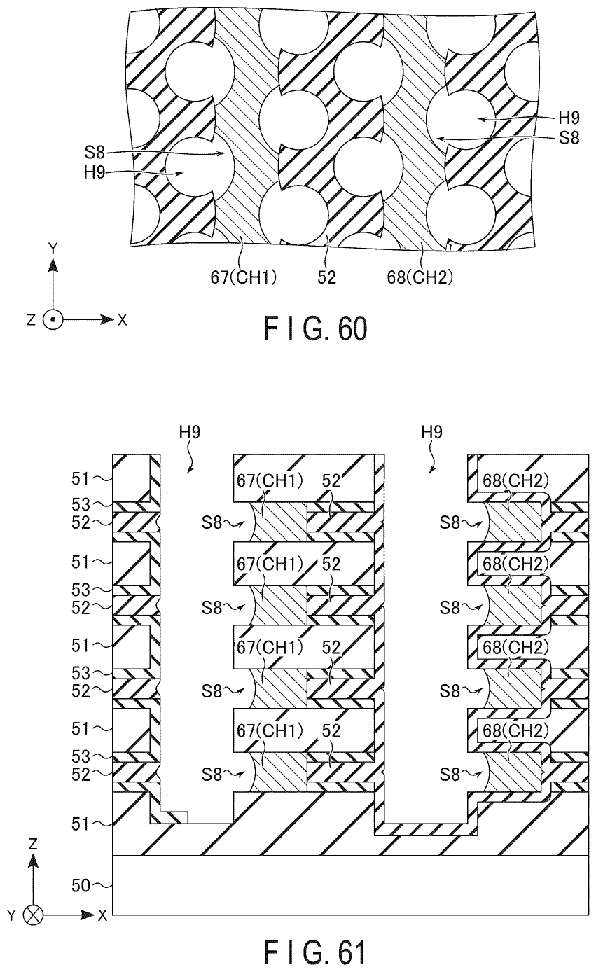

As shown in FIGS. 60 and 61, in the stacked structure, a plurality of holes H9 are provided in the prospective region where the conductive pillars WP1 and WP2 are to be provided. More specifically, the sacrificial film 80 and the stop film 79 provided in the prospective region where the plurality of conductive pillars WP1 are to be provided and the sacrificial film 78 and the stop film 77 provided in the prospective region where the plurality of conductive pillars WP2 are to be provided are removed. The sacrificial films 78 and 80 contain the same material (for example, polysilicon) and hence are simultaneously removed by one etching process. The stop films 77 and 79 contain the same material (for example, silicon oxide) and hence are simultaneously removed by one etching process. With this process, the semiconductor film 67 is exposed in the hole H9 corresponding to the conductive pillar WP1. The semiconductor film 68 is exposed in the hole H9 corresponding to the conductive pillar WP2.

The semiconductor films 67 and 68 are then partially removed through each of the plurality of holes H9. The semiconductor films 67 and 68 contain the same material (for example, amorphous silicon) and hence are simultaneously removed by one etching process. This forms a groove S8 in the prospective region where the memory structures MS1 and MS2 are to be provided. The residual semiconductor film 67 functions as the channel structure CH1. The residual semiconductor film 68 functions as the channel structure CH2.

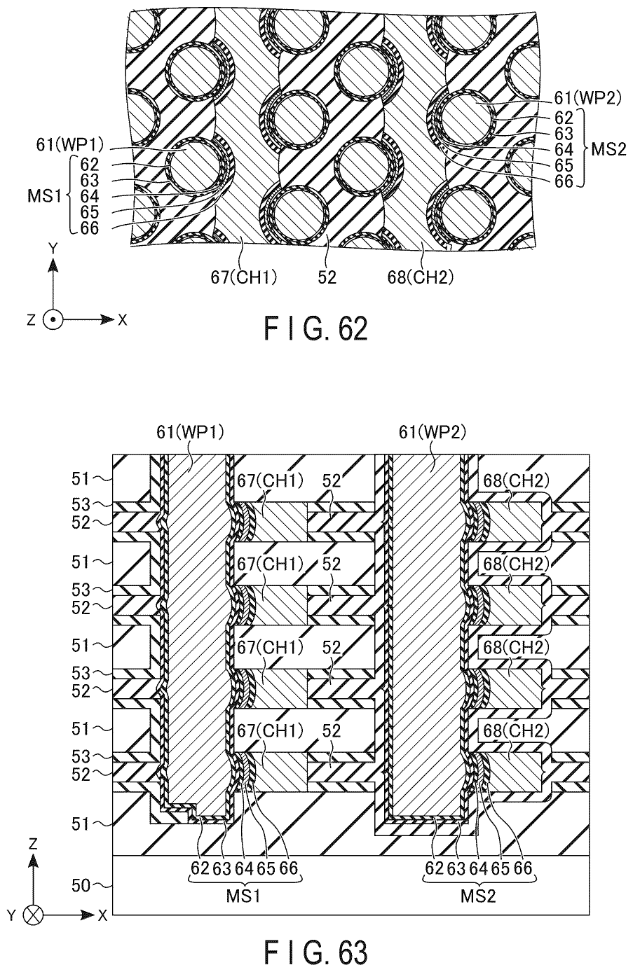

As shown in FIGS. 62 and 63, the insulator film 66, the charge storage film 65, and the insulator film 64 are formed in the groove S8 in each layer in this order. This fills each groove S8. Note that at the time of forming the charge storage films 65, the charge storage film 65 formed in each of the plurality of holes H9 is etched back. This separates the charge storage films 65 filling the grooves S8 from each other. Likewise, at the time of forming the insulator films 64, the insulator film 64 formed in each of the plurality of holes H9 is etched back. This separates the insulator films 64 filling the grooves S8 in the respective layers from each other. Note that the charge storage film 65 can be formed while containing, for example, amorphous silicon.

The insulator film 63, the insulator film 62, and the conductor film 61 are then formed in each of the plurality of holes H9 in this order. With this process, each of the plurality of holes H9 is filled. The portions of the insulator films 63 and 62 and the conductor film 61 which are provided above the hole H9 (that is, the upper surface of the uppermost insulator layer 51) are removed by, for example, CMP.

Subsequently, structures such as the contacts CV and the word lines WL are formed above the stacked structure including the layer units LU. In addition, the amorphous silicon is crystallized into polysilicon by annealing. In the above manner, a memory device 3 is formed.

### 2.3 Effects According to Second Embodiment

According to the second embodiment, at the time of filling the hole H8, the insulator film 53 is formed in the hole H8. At the time of filling the hole H9, the insulator film 52 is formed in the hole H9, and the sacrificial film 74 filling the hole H8 is partially replaced by the insulator film 52. This makes it possible to suppress increases in the diameters of the portions of the conductive pillars WP1 and WP2 which are in contact with the insulator INS. Accordingly, it is possible to reduce the area occupied by one memory cell.

Note that, of the space formed by partially removing the sacrificial film 74, the space between the stop film 75 and the insulator film 53 has a width d1 smaller than a width d2 of the space sandwiched between the insulator films 53 in the Z direction in each layer. Accordingly, at the time of replacing part of the sacrificial film 74 with the insulator film 52 through the groove S6, the space with the width d1 can be filled with the insulator film 52 before the space with the width d2 is filled with the insulator film 52. Of the space formed by partially removing the sacrificial film 74, the space sandwiched between the insulator layers 51 in the Z direction in each layer has a width d3 larger than a width d2 of the space sandwiched between the insulator films 53 in the Z direction in each layer. Accordingly, at the time of replacing part of the sacrificial film 74 with the insulator film 52 via the groove S6, part of the space with the width d3 is not filled even after the space with the width d2 is filled with the insulator film 52. This makes it possible to properly fill the groove S6 with the insulator film 52 and the semiconductor film 68.

### 3. Modifications and Like

Various modifications can be applied to the above embodiments.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A memory device comprising:
a first conductive pillar and a second conductive pillar each extending in a first direction, and arranged in a second direction intersecting the first direction;
a third conductive pillar and a fourth conductive pillar each extending in the first direction at a position shifted from the first conductive pillar and the second conductive pillar in a third direction intersecting the first direction and the second direction, and arranged in the second direction;
a first semiconductor film provided between the first conductive pillar and the third conductive pillar at a first position in the first direction;
a second semiconductor film provided between the second conductive pillar and the fourth conductive pillar at the first position;
a first insulator film provided between the second conductive pillar and the third conductive pillar at the first position;
a first charge storage film provided between the first conductive pillar and the first semiconductor film;
a second charge storage film provided between the second conductive pillar and the second semiconductor film;
a third charge storage film provided between the third conductive pillar and the first semiconductor film; and
a fourth charge storage film provided between the fourth conductive pillar and the second semiconductor film,
wherein the third conductive pillar is located between the first conductive pillar and the second conductive pillar in the second direction, and
the second conductive pillar is located between the third conductive pillar and the fourth conductive pillar in the second direction.

2. The device according to claim 1, wherein the first conductive pillar, the second conductive pillar, the third conductive pillar, and the fourth conductive pillar are arranged in a staggered pattern when viewed in the first direction.

3. The device according to claim 1, further comprising:
a third semiconductor film provided between the first conductive pillar and the third conductive pillar at a second position different from the first position in the first direction;
a fourth semiconductor film provided between the second conductive pillar and the fourth conductive pillar at the second position; and
a second insulator film provided between the second conductive pillar and the third conductive pillar at the second position.

4. The device according to claim 1, further comprising:
a first conductor layer electrically connected to each of the first conductive pillar and the second conductive pillar; and
a second conductor layer electrically connected to each of the third conductive pillar and the fourth conductive pillar.

5. The device according to claim 1, wherein each of the first conductive pillar and the third conductive pillar has a shape different from a shape of each of the second conductive pillar and the fourth conductive pillar when viewed in the first direction.

6. The device according to claim 5, wherein each of the first conductive pillar and the third conductive pillar has a substantially true circular shape, and each of the second conductive pillar and the fourth conductive pillar has a substantially circular shape with a recess, when viewed in the first direction.

7. The device according to claim 5, wherein each of the first conductive pillar and the third conductive pillar has a stepped portion in the first direction at a lower portion.

8. The device according to claim 7, wherein each of the second conductive pillar and the fourth conductive pillar has a substantially flat shape at a lower portion.

9. The device according to claim 7, wherein a lower portion of each of the first conductive pillar and the third conductive pillar has a first portion and a second portion having different lengths in the first direction,
the first portion of the first conductive pillar and the second portion of the first conductive pillar are arranged in the second direction, and
the first portion of the third conductive pillar and the second portion of the third conductive pillar are arranged in the second direction.

10. The device according to claim 9, wherein the second portion of the first conductive pillar is longer than the first portion of the first conductive pillar in the first direction and located on a side of the first semiconductor film, and
the second portion of the third conductive pillar is longer than the first portion of the third conductive pillar in the first direction and located on a side of the first semiconductor film.

11. The device according to claim 1, wherein the first insulator film includes a first oxide film type and a second oxide film type different from each other.

12. The device according to claim 11, wherein the second oxide film type includes a first portion sandwiched in the first direction by the first oxide film at the first position.

13. The device according to claim 12, wherein the first oxide film type includes a portion that covers a lower portion and a side portion of each of the first conductive pillar and the third conductive pillar, and
the second oxide film type includes a second portion that covers a lower portion and a side portion of each of the second conductive pillar and the fourth conductive pillar.

14. The device according to claim 13, wherein the lower portion of each of the first conductive pillar and the third conductive pillar includes a first portion and a second portion that have different lengths in the first direction, and
the first oxide film type covers the first portion and does not cover the second portion.

15. The device according to claim 13, wherein the second portion of the second oxide film type has a width equal to or larger than a width of the first portion of the second oxide film type.

16. The device according to claim 1, wherein each of the first charge storage film, the second charge storage film, the third charge storage film, and the fourth charge storage film contains polysilicon.
